(19) United States
(12) Patent Application Publication
(10) Pub. No.: US 2025/0113642 A1
(43) Pub. Date: Apr. 3, 2025

(54) IMAGE DISPLAY DEVICE AND ELECTRONIC APPARATUS

(71) Applicant: Sony Semiconductor Solutions Corporation, Kanagawa (JP)

(72) Inventors: Seiichiro Jinta, Kanagawa (JP); Ryosuke Saito, Kanagawa (JP); Mitsuro Asano, Kanagawa (JP)

(21) Appl. No.: 18/704,689

(22) PCT Filed: Dec. 6, 2022
(86) PCT No.: PCT/JP22/44965

§ 371 Date: Nov. 25, 2024

(30) Foreign Application Priority Data
Dec. 13, 2021 (JP) 2021-202043

(51) Int. Cl. H10F 55/00; G03B 9/08; H10F 39/00; H10H 29/30; H10H 29/45

(52) U.S. Cl. CPC H10F 55/18; G03B 9/08; H10F 39/806; H10H 29/352; H10H 29/45

(57) ABSTRACT

Image display devices with suppressed generation of diffracted light are disclosed. In one example, an image display device includes pixels arranged two-dimensionally, and a pixel region including some of the pixels that has transmissive windows that transmit visible light and have different sizes. The pixels include a self-light-emitting element, a light emitting region in which light is emitted by the self-light-emitting element, and a non-light emitting region including the transmissive window.

### TECHNICAL FIELD

The present disclosure relates to an image display device and an electronic apparatus.

### BACKGROUND ART

In recent electronic apparatuses such as smartphones, mobile phones, and personal computers (PCs), various sensors such as cameras are mounted in a frame (bezel) of a display panel. The number of mounted sensors also tends to increase, and there are a sensor for face authentication, an infrared sensor, a moving object detection sensor, and the like in addition to cameras. On the other hand, from the viewpoint of design and the tendency of making electronic apparatuses lighter, thinner, shorter, and smaller, an outer size of the electronic apparatus is required to be made as compact as possible without affecting a screen size, causing a bezel width to become narrower. In view of such a background, a technique has been proposed in which an image sensor module is arranged immediately below a display panel, and subject light having passed through the display panel is captured by the image sensor module. In order to arrange the image sensor module immediately below the display panel, it is necessary to make the display panel transparent (see Patent Document 1).

### CITATION LIST

### Patent Document

Patent Document 1: Japanese Patent Application Laid-Open No. 2021-39328

### SUMMARY OF THE INVENTION

### Problems to be Solved by the Invention

In each pixel of the display panel, however, opaque members such as a pixel circuit and a wiring pattern are arranged, and an insulating layer having low transmittance is also arranged. Therefore, when the image sensor module is arranged immediately below the display panel, light incident on the display panel is irregularly reflected, refracted, and diffracted in the display panel, and then impinges on the image sensor module in a state where light caused by the reflection, the refraction, and the diffraction (hereinafter, referred to as diffracted light) is generated. When imaging is performed with the diffracted light generated, the image quality of a subject image deteriorates.

It is therefore an object of the present disclosure to provide an image display device and an electronic apparatus capable of suppressing the generation of diffracted light.

### Solutions to Problems

In order to solve the above-described problems, according to the present disclosure, provided is an image display device including a plurality of pixels arranged two-dimensionally; and
a pixel region including some pixels of the plurality of pixels, the pixel region including two or more transmissive windows that transmit visible light and have different sizes, in which
the some pixels include:
a self light-emitting element;
a light emitting region in which light is emitted by the self light-emitting element; and
a non-light emitting region including the transmissive window.

Each of the two or more transmissive windows may be arranged for a corresponding one of the pixels or arranged across two or more of the pixels.

The some pixels may include two or more pixels, and each of the two or more pixels may include one of the two or more transmissive windows having different sizes.

The light emitting region in each of the two or more pixels may include a plurality of the self light-emitting elements that emits light in different colors.

The two or more pixels may include:
a first pixel including the self light-emitting element, the light emitting region, and the non-light emitting region including the transmissive window having a first size; and
a second pixel including the self light-emitting element, the light emitting region, and the non-light emitting region including the transmissive window having a second size different from the first size.

The transmissive window having the first size and the transmissive window having the second size may be similar in shape to each other.

The pixel region may include:
a first pixel group in which a plurality of the first pixels is two-dimensionally arranged; and
a second pixel group in which a plurality of the second pixels is two-dimensionally arranged,
a ratio of an interval between the transmissive windows to a width of each of the transmissive windows in the first pixel group may be a first prime number, and
a ratio of an interval between the transmissive windows to a width of each of the transmissive windows in the second pixel group may be a second prime number different from the first prime number.

The plurality of first pixels in the first pixel group may be arranged in multiple rows and columns in a first direction and a second direction,
the plurality of second pixels in the second pixel group may be arranged in multiple rows and columns in the first direction and the second direction,
a ratio of an interval between the transmissive windows in the first pixel group to a width of each of the transmissive windows in the first direction may be equal to a ratio of an interval between the transmissive windows in the first pixel group to a width of each of the transmissive windows in the second direction, and
a ratio of an interval between the transmissive windows in the second pixel group to a width of each of the transmissive windows in the first direction may be equal to a ratio of an interval between the transmissive windows in the second pixel group to a width of each of the transmissive windows in the second direction.

One of the first prime number or the second prime number may be 2, and the other may be 3.

The some pixels may include three or more pixels,
the three or more pixels may include any one of three or more of the transmissive windows having different sizes, and ratios of respective intervals of the three or more transmissive windows to respective widths of the three or more transmissive windows may be different prime numbers.

A pixel array unit including the plurality of pixels; and
a light regulating member arranged on a surface side opposite to a display surface of the pixel array unit and arranged so as to overlap the pixel array unit as viewed from above may be further included, in which
the light regulating member may selectively generate one of two or more visible light transmissive portions having different sizes at a position overlapping a corresponding one of the transmissive windows as viewed from above.

A size of each of the visible light transmissive portions may be smaller than or equal to the size of each of the transmissive windows.

The some pixels may include two or more pixels,
each of the two or more pixels may include the two or more transmissive windows having different sizes, and the light regulating member may selectively generate the two or more visible light transmissive portions different in position and size in accordance with positions and the sizes of the two or more transmissive windows.

The light regulating member may selectively generate one of the two or more visible light transmissive portions under electrical control or mechanical control.

The light regulating member may include a liquid crystal shutter configured to partially vary visible light transmittance, and
the liquid crystal shutter may vary a transmittance of a region corresponding to the two or more transmissive windows to generate any one of the two or more visible light transmissive portions.

According to the present disclosure, provided is an image display device including:
a pixel array unit including a plurality of pixels arranged two-dimensionally; and
a light regulating member arranged on a surface side opposite to a display surface of the pixel array unit and arranged so as to overlap the pixel array unit as viewed from above, in which
a pixel region including some pixels of the plurality of pixels includes a transmissive window that transmits visible light,
the some pixels include:
a self light-emitting element;
a light emitting region in which light is emitted by the self light-emitting element; and
a non-light emitting region including the transmissive window, and
the light regulating member selectively generates one of two or more visible light transmissive portions having different sizes at a position overlapping the transmissive window as viewed from above.

The light regulating member may include a liquid crystal shutter configured to partially vary visible light transmittance, and
the liquid crystal shutter may vary transmittances of two or more partial regions in a region corresponding to the transmissive window to generate any one of the two or more visible light transmissive portions.

The non-light emitting region may be arranged at a position overlapping a light receiving device configured to receive light incident through the plurality of pixels as a display surface side of the plurality of pixels is viewed from above.

According to the present disclosure, provided is an electronic apparatus including:
an image display device including a plurality of pixels arranged two-dimensionally; and
a light receiving device configured to receive light incident through the image display device, in which
the image display device includes a pixel region including some pixels of the plurality of pixels,
the pixel region includes an opening through which visible light is transmitted,
the some pixels include:
a self light-emitting element;
a light emitting region in which light is emitted by the self light-emitting element; and
a non-light emitting region including the opening, at least a part of the pixel region is arranged so as to overlap the light receiving device as a display surface side of the image display device is viewed from above, and
the light receiving device receives two or more rays of subject light selectively transmitted through two or more of the openings having different sizes or two or more regions having different sizes in the opening.

A signal processing unit configured to cancel out a high-order light component of diffracted light on the basis of a light reception signal based on the two or more rays of subject light received by the light receiving device may be further included.

The light receiving device may include at least one of: an imaging sensor configured to photoelectrically convert light incident through the non-light emitting region; a distance measuring sensor configured to receive light incident through the non-light emitting region to measure a distance; or a temperature sensor configured to measure a temperature on the basis of light incident through the non-light emitting region.

### BRIEF DESCRIPTION OF DRAWINGS

FIG. 1 is a diagram illustrating an example of a specific location of a sensor arranged immediately below a display panel indicated by a broken line.

FIG. 2A is a diagram illustrating an example in which two sensors are arranged side by side on a back surface side on an upper side of a center of the display panel.

FIG. 2B is a diagram illustrating an example in which sensors 5 are arranged at four corners of the display panel.

FIG. 3 is a diagram schematically illustrating a structure of a pixel in a first pixel region and a structure of a pixel in a second pixel region.

FIG. 4 is a cross-sectional view of an image sensor module.

FIG. 5 is a diagram schematically illustrating an optical configuration of the image sensor module.

FIG. 6 is a diagram for describing an optical path until light from a subject is formed as an image on an image sensor.

FIG. 7 is a circuit diagram illustrating a basic configuration of a pixel circuit including an organic light emitting diode (OLED).

FIG. 8 is a planar layout diagram of the pixels in the second pixel region.

FIG. 9 is a cross-sectional view of each pixel in the second pixel region.

FIG. 10 is a cross-sectional view illustrating a layered structure of a display layer.

FIG. 11 is a diagram for describing a diffraction phenomenon that generates diffracted light.

FIG. 12 is a planar layout diagram of an image display device 1 according to an embodiment that solves a problem that may occur in the planar layout in FIG. 11.

FIG. 13 is a cross-sectional view illustrating a first example of a cross-sectional structure of the first pixel region.

FIG. 14 is a diagram illustrating an example in which one transmissive window is provided across three pixels.

FIG. 15 is a diagram for describing a bright-line condition of a diffraction grating.

FIG. 16 is a diagram illustrating the bright-line condition represented by a diffraction angle.

FIG. 17 is a diagram illustrating the bright-line condition represented by a light incident position on a screen.

FIG. 18 is a diagram illustrating a dark-line condition of a single slit.

FIG. 19 is a diagram illustrating an intensity distribution curve of light passing through the single slit.

FIG. 20 is a diagram illustrating how to suppress diffracted light in the present embodiment.

FIG. 21 is a diagram illustrating an example of an image obtained by imaging subject light transmitted through the display panel.

FIG. 22A is a plan view illustrating a width of and an interval between the transmissive windows in a case where m=2.

FIG. 22B is a diagram illustrating light intensity of diffracted light in a case where m=2.

FIG. 22C is a diagram illustrating brightness of high-order light components from the 0th-order light to the 20th-order light contained in the diffracted light.

FIG. 23A is a plan view illustrating a width of and an interval (pitch) between the transmissive windows in a case where m=3.

FIG. 23B is a diagram illustrating light intensity of diffracted light in a case where m=3.

FIG. 23C is a diagram illustrating brightness of high-order light components from the 0th-order light to the 20th-order light contained in the diffracted light.

FIG. 24A is a diagram illustrating a relationship between an opening width and an opening interval of the transmissive windows.

FIG. 24B is a diagram illustrating brightness or darkness of each high-order light component contained in diffracted light in a case where m is changed in a plurality of ways.

FIG. 25A is a plan view of an electronic apparatus.

FIG. 25B is a plan view of each pixel in the first pixel region.

FIG. 25C is a plan view of each pixel in the first pixel region.

FIG. 26A is a pixel layout diagram of the first pixel region arranged at a position overlapping a first sensor.

FIG. 26B is a pixel layout diagram of the first pixel region arranged at a position overlapping a second sensor.

FIG. 26C is a diagram illustrating a structure of each pixel in the second pixel region.

FIG. 27 is a block diagram related to image processing that is performed by an electronic apparatus according to a first specific example.

FIG. 28 is a schematic plan view and a cross-sectional view of an electronic apparatus including an image display device according to a second specific example.

FIG. 29A is a plan view illustrating pixels in the first pixel region arranged at a position overlapping a sensor.

FIG. 29B is a plan view of a light regulating member.

FIG. 29C is a diagram illustrating a switching operation of a liquid crystal shutter.

FIG. 30 is a block diagram related to image processing that is performed by the electronic apparatus according to the second specific example.

FIG. 31A is a plan view illustrating pixels in the first pixel region arranged at a position overlapping a sensor.

FIG. 31B is a plan view of a liquid crystal shutter corresponding to FIG. 31A.

FIG. 31C is a diagram illustrating a switching operation of the liquid crystal shutter.

FIG. 32A is a diagram illustrating an internal state of a vehicle from a rear side to a front side of the vehicle.

FIG. 32B is a diagram illustrating an internal state of the vehicle from an oblique rear side to an oblique front side of the vehicle.

FIG. 33A is a front view of a digital camera as a second application example of the electronic apparatus.

FIG. 33B is a rear view of the digital camera.

FIG. 34A is an external view of a head mounted display (HMD) as a third application example of the electronic apparatus.

FIG. 34B is an external view of smart glasses.

FIG. 35 is an external view of a television (TV) as a fourth application example of the electronic apparatus.

FIG. 36 is an external view of a smartphone as a fifth application example of the electronic apparatus.

### MODE FOR CARRYING OUT THE INVENTION

Hereinafter, embodiments of an image display device and an electronic apparatus will be described with reference to the drawings. Although principal components of the image display device and the electronic apparatus will be mainly described below, the image display device and the electronic apparatus may include components and functions that are not illustrated or described. The following description does not exclude components and functions that are not illustrated or described.

### First Embodiment

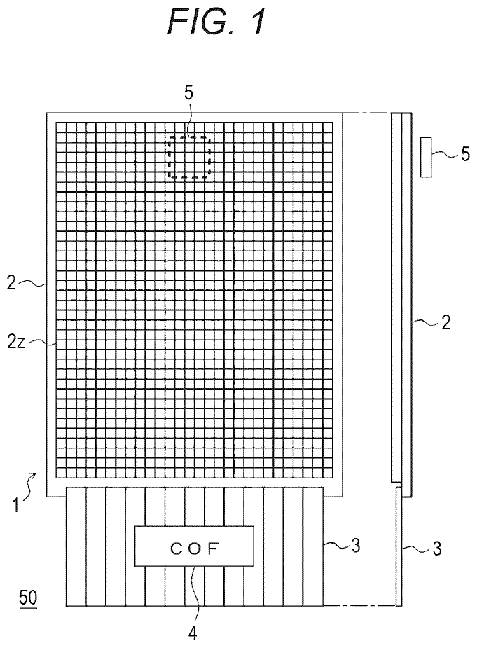

FIG. 1 is a plan view and a cross-sectional view of an electronic apparatus 50 including an image display device 1 according to a first embodiment of the present disclosure. As illustrated in the drawing, the image display device 1 according to the present embodiment includes a display panel 2. For example, a flexible printed circuit (FPC) 3 is connected to the display panel 2. The display panel 2 is obtained by layering a plurality of layers on, for example, a glass substrate or a transparent film, and a plurality of pixels is arranged vertically and horizontally on a display surface 2z. A chip on film (COF) 4 incorporating at least a part of a drive circuit of the display panel 2 is mounted on the FPC 3. Note that the drive circuit may be layered on the display panel 2 as a chip on glass (COG). The display panel 2 includes a pixel array unit in which a plurality of pixels is two-dimensionally arranged. As will be described later, some pixels in the pixel array unit according to the present embodiment have a transmissive window that transmits visible light.

In the image display device 1 according to the present embodiment, various sensors 5 that receive light through the display panel 2 can be arranged immediately below the display panel 2. In the present specification, a configuration including the image display device 1 and the sensor 5 is referred to as the electronic apparatus 50. While a type of the sensor 5 provided in the electronic apparatus 50 is not particularly limited, examples of which include, for example, an imaging sensor that photoelectrically converts light incident through the display panel 2, a distance measuring sensor that projects light through the display panel 2 and receives light reflected by a target object through the display panel 2 to measure a distance to the target object, a temperature sensor that measures a temperature on the basis of light incident through the display panel 2, and the like. In this way, the sensor 5 arranged immediately below the display panel 2 has at least a function of a light receiving device that receives light. Note that the sensor 5 may have a function of a light emitting device that projects light through the display panel 2.

In FIG. 1, an example of a specific location of the sensor 5 arranged immediately below the display panel 2 is indicated by a broken line. As illustrated in FIG. 1, for example, the sensor 5 is arranged on a back surface side on an upper side of a center of the display panel 2. Note that the arrangement location of the sensor 5 in FIG. 1 is an example, and any arrangement location of the sensor 5 may be adopted. As illustrated in the drawing, arranging the sensor 5 on the back surface side of the display panel 2 eliminates the need of arranging the sensor 5 on a lateral side of the display panel 2, so that a bezel of the electronic apparatus 50 can be minimized, and almost the entire area of a front surface side of the electronic apparatus 50 can be used as the display panel 2.

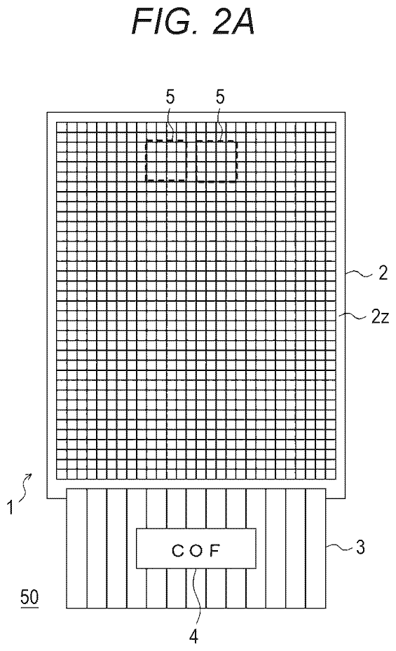

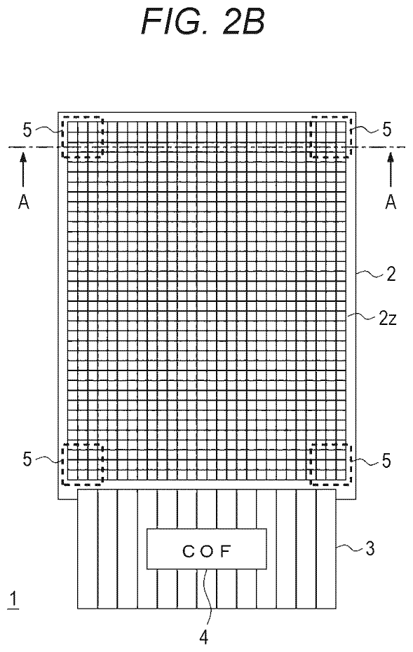

FIG. 1 illustrates an example in which the sensor 5 is arranged at one place of the display panel 2, but the sensor 5 may be arranged at a plurality of places as illustrated in FIG. 2A or 2B. FIG. 2A illustrates an example in which two sensors 5 are arranged side by side on the back surface side on the upper side of the center of the display panel 2. Furthermore, FIG. 2B illustrates an example in which the sensors 5 are arranged at four corners of the display panel 2. As illustrated in FIG. 2B, the sensors 5 are arranged at four corners of the display panel 2 for the following reason. Since a pixel region overlapping the sensor 5 in the display panel 2 is devised to increase transmittance, there is a possibility that a slight difference occurs in display quality from a surrounding pixel region. Yes. When a human gazes at a center of a screen, the human can grasp details of a central portion of the screen, which is a central visual field, and can notice the slight difference. However, a degree of detail visibility of an outer peripheral portion, which is a peripheral visual field, becomes low. Since the center of the screen is often seen in a normal display image, it is recommended to arrange the sensors 5 at the four corners in order to make the difference unnoticeable.

In a case of arranging the plurality of sensors 5 on the back surface side of the display panel 2 as illustrated in FIGS. 2A and 2B, types of the plurality of sensors 5 may be the same or different. For example, a plurality of image sensor modules 9 having different focal lengths may be arranged, or different types of the sensors 5 such as the imaging sensor 5 and a time of flight (ToF) sensor 5 may be arranged.

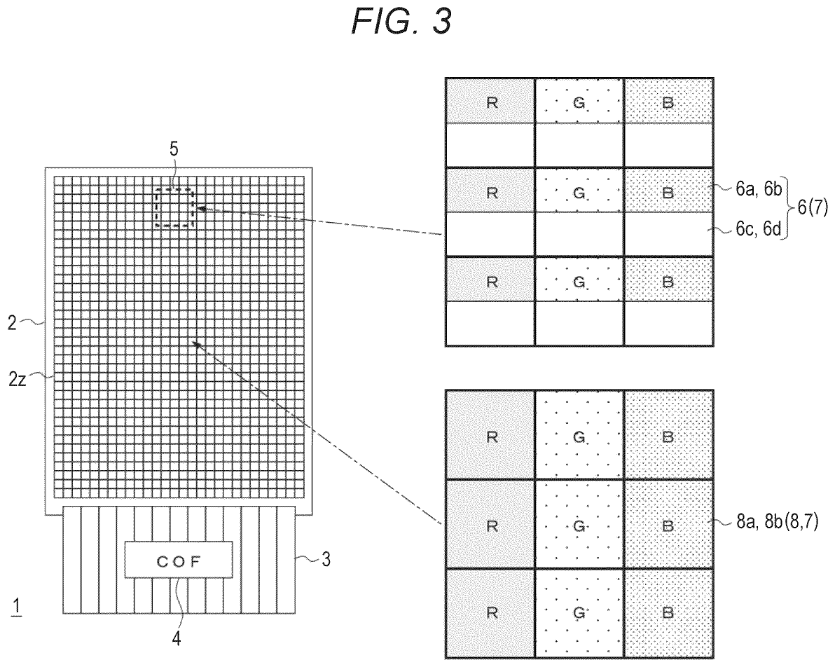

In the present embodiment, there is a difference in pixel structure between a pixel region (first pixel region) overlapping the sensor 5 on the back surface side and a pixel region (second pixel region) not overlapping the sensor 5. FIG. 3 is a diagram schematically illustrating a structure of a pixel 7 in a first pixel region 6 and a structure of a pixel 7 in a second pixel region 8. The pixel 7 in the first pixel region 6 includes a first self light-emitting element 6a, a first light emitting region 6b, and a non-light emitting region 6c. The first light emitting region 6b is a region in which light is emitted by the first self light-emitting element 6a. The non-light emitting region 6c includes a transmissive window 6d having a predetermined shape to transmit visible light although light is not emitted by the first self light-emitting element 6a. The pixel 7 in the second pixel region 8 includes a second self light-emitting element 8a and a second light emitting region 8b. Light is emitted by the second self light-emitting element 8a in the second light emitting region 8b, and the second light emitting region 8b is larger in area than the first light emitting region 6b. The first light emitting region 6b and the second light emitting region 8b include a plurality of the first self light-emitting elements 6a and a plurality of the second self light-emitting elements 8a that emit light in different colors, respectively.

Typical examples of the first self light-emitting element 6a and the second self light-emitting element 8a include an organic electroluminescence (EL) element (hereinafter, also referred to as organic light emitting diode (OLED)). The self light-emitting element need not have a backlight, so that at least a part of the self light-emitting element can be made transparent. Hereinafter, an example in which the OLED is used as the self light-emitting element will be mainly described.

Note that, rather than making the structure of the pixel 7 different between the pixel region overlapping the sensor 5 and the pixel region not overlapping the sensor 5, all the pixels 7 in the display panel 2 may have the same structure. In this case, it is only required that all the pixels 7 be configured by the first light emitting region 6b and the non-light emitting region 6c in FIG. 3 such that the sensor 5 can be overlapped and arranged at any location in the display panel 2.

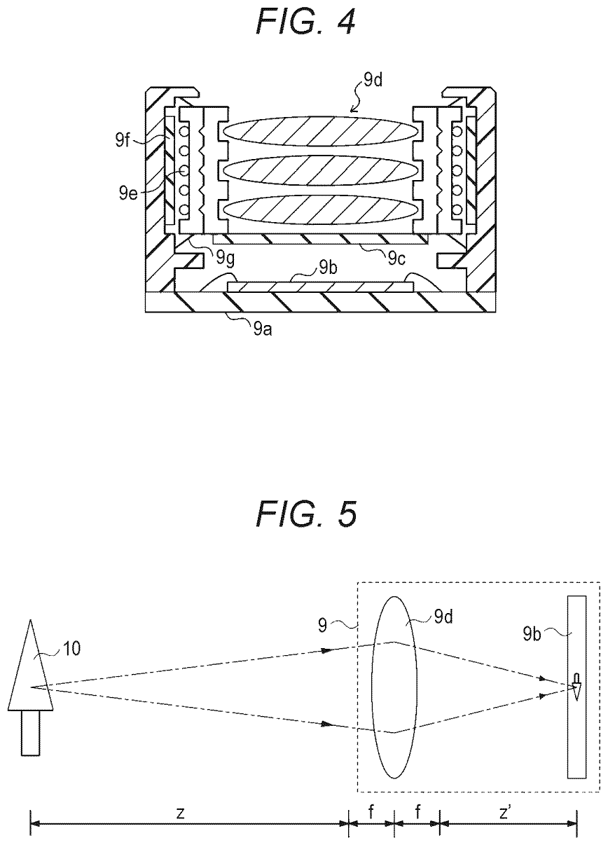

FIG. 4 is a cross-sectional view of the image sensor module 9. As illustrated in FIG. 4, the image sensor module 9 includes an image sensor 9b mounted on a support substrate 9a, an infrared ray (IR) cut filter 9c, a lens unit 9d, a coil 9e, a magnet 9f, and a spring 9g. The lens unit 9d includes one or a plurality of lenses. The lens unit 9d is movable in an optical axis direction in accordance with a direction of a current flowing through the coil 9e. Note that an internal configuration of the image sensor module 9 is not limited to that illustrated in FIG. 4.

FIG. 5 is a diagram schematically illustrating an optical configuration of the image sensor module 9. Light from a subject 10 is refracted by the lens unit 9d, and formed as an image on the image sensor 9b. As an amount of light incident on the lens unit 9d increases, an amount of light received by the image sensor 9b also increases, and sensitivity improves accordingly. In a case of the present embodiment, the display panel 2 is arranged between the subject 10 and the lens unit 9d. When light from the subject 10 is transmitted through the display panel 2, it is important to suppress absorption, reflection, and diffraction in the display panel 2.

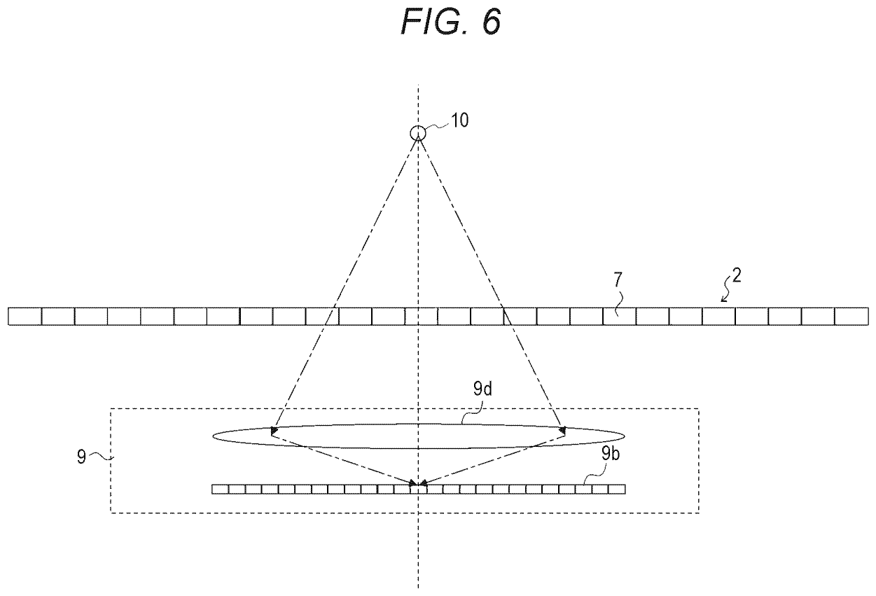

FIG. 6 is a diagram for describing an optical path until light from the subject 10 is formed as an image on the image sensor 9b. In FIG. 6, each pixel 7 of the display panel 2 and each pixel 7 of the image sensor 9b are schematically represented by rectangular squares. As illustrated in the drawing, a size of each pixel 7 of the display panel 2 is much larger than a size of each pixel 7 of the image sensor 9b. Light from a specific position of the subject 10 passes through the transmissive window 6d of the display panel 2, is refracted by the lens unit 9d of the image sensor module 9, and is formed as an image at a specific pixel 7 on the image sensor 9b. As described above, the light from the subject 10 is transmitted through the plurality of transmissive windows 6d provided in the plurality of pixels 7 in the first pixel region 6 of the display panel 2, and impinges on the image sensor module 9.

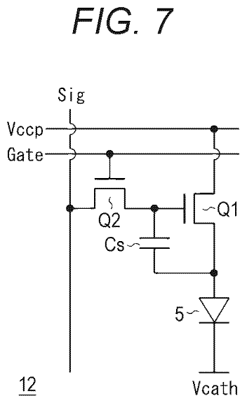

FIG. 7 is a circuit diagram illustrating a basic configuration of a pixel circuit 12 including an OLED 5. The pixel circuit 12 in FIG. 7 includes a drive transistor Q1, a sampling transistor Q2, and a pixel capacitance Cs, in addition to the OLED 5. The sampling transistor Q2 is connected between a signal line Sig and a gate of the drive transistor Q1. To a gate of the sampling transistor Q2, a scanning line Gate is connected. The pixel capacitance Cs is connected between the gate of the drive transistor Q1 and an anode electrode of the OLED 5. The drive transistor Q1 is connected between a power supply voltage node Vccp and the anode of the OLED 5.

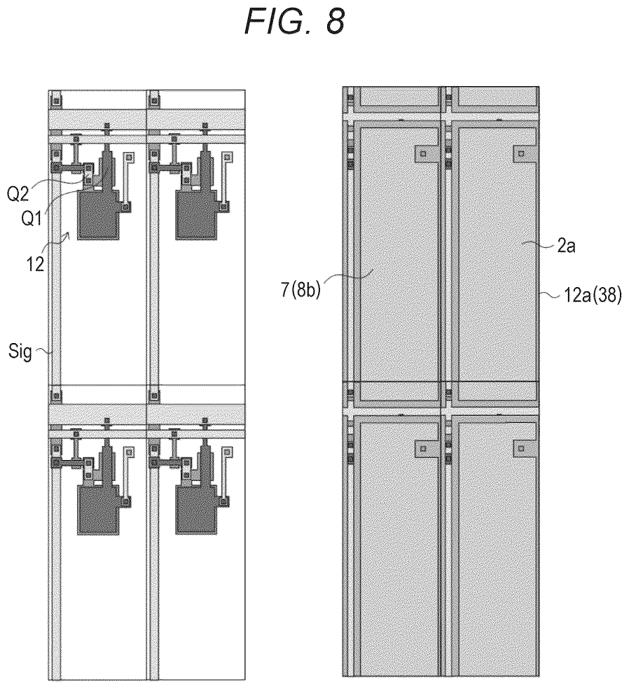

FIG. 8 is a planar layout diagram of the pixels 7 in the second pixel region 8 in which the sensor 5 is not arranged immediately below. The pixels 7 in the second pixel region 8 have a typical pixel configuration. Each pixel 7 includes a plurality of color pixels 7 (for example, three RGB color pixels 7). FIG. 8 illustrates a planar layout of a total of four color pixels 7 including two color pixels 7 horizontally arranged and two color pixels 7 vertically arranged. Each color pixel 7 includes the second light emitting region 8b. The second light emitting region 8b extends almost all over the color pixel 7. In the second light emitting region 8b, the pixel circuit 12 including the second self light-emitting element 8a (OLED 5) is arranged. Left two columns of FIG. 8 illustrate a planar layout below an anode electrode 12a, and right two columns of FIG. 8 illustrate a planar layout of the anode electrode 12a and a display layer 2a arranged on the anode electrode 12a.

As illustrated in the right two columns of FIG. 8, the anode electrode 12a and the display layer 2a are arranged almost all over the color pixel 7, so that the entire area of the color pixel 7 serves as the second light emitting region 8b that emits light.

As illustrated in the left two columns of FIG. 8, the pixel circuit 12 of the color pixel 7 is arranged in an upper half region in the color pixel 7. Furthermore, on an upper end side of the color pixel 7, a wiring pattern for the power supply voltage Vccp and a wiring pattern for the scanning line are arranged extending in a horizontal direction X. Furthermore, a wiring pattern of the signal line Sig is arranged along a boundary of the color pixel 7 in a vertical direction Y.

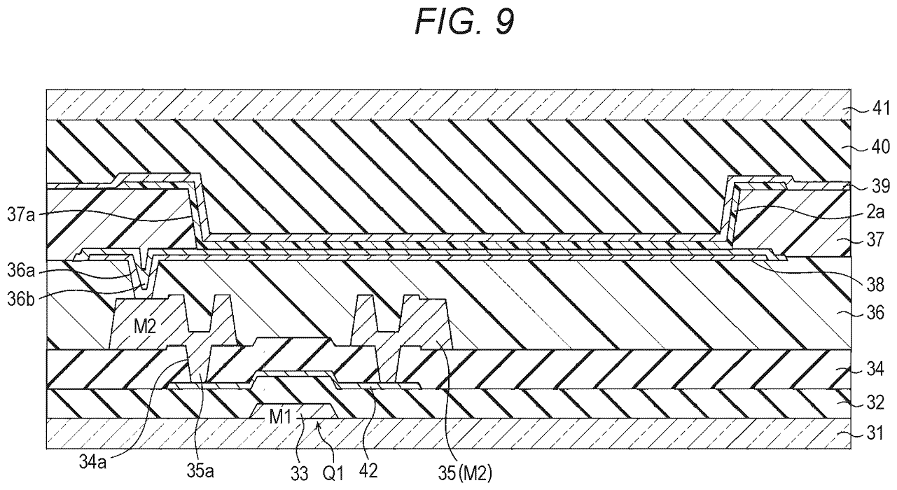

FIG. 9 is a cross-sectional view of the pixel 7 (the color pixel 7) in the second pixel region 8 in which the sensor 5 is not arranged immediately below. FIG. 9 illustrates a cross-sectional structure taken along A-A line in FIG. 8, and more specifically illustrates a cross-sectional structure around the drive transistor Q1 in the pixel circuit 12. Note that the cross-sectional views illustrated in the drawings attached to the present specification, including FIG. 9, emphasize and illustrate a characteristic layer configuration, and a ratio of vertical and horizontal lengths does not necessarily coincide with a planar layout.

An upper surface in FIG. 9 is a display surface side of the display panel 2, and a bottom surface in FIG. 9 is a side on which the sensor 5 is arranged. From the bottom surface side to the upper surface side (a light emission side) in FIG. 9, a first transparent substrate 31, a first insulating layer 32, a first wiring layer (a gate electrode) 33, a second insulating layer 34, a second wiring layer (source wiring or drain wiring) 35, a third insulating layer 36, an anode electrode layer 38, a fourth insulating layer 37, a display layer 2a, a cathode electrode layer 39, a fifth insulating layer 40, and a second transparent substrate 41 are sequentially layered.

The first transparent substrate 31 and the second transparent substrate 41 are desirably formed by, for example, quartz glass, a transparent film, or the like having excellent visible light transmittance. Alternatively, either one of the first transparent substrate 31 and the second transparent substrate 41 may be formed by quartz glass, and the other one may be formed by a transparent film.

Note that, from the viewpoint of production, a colored film having a relatively low transmittance, for example, a polyimide film may be used. Alternatively, at least one of the first transparent substrate 31 or the second transparent substrate 41 may be formed by a transparent film. On the first transparent substrate 31, the first wiring layer (M1) 33 for connection of each circuit element in the pixel circuit 12 is arranged.

On the first transparent substrate 31, the first insulating layer 32 is arranged so as to cover the first wiring layer 33. The first insulating layer 32 has, for example, a layered structure of a silicon nitride layer and a silicon oxide layer having excellent visible light transmittance. On the first insulating layer 32, a semiconductor layer 42 in which a channel region of each transistor in the pixel circuit 12 is formed is arranged. FIG. 9 schematically illustrates a cross-sectional structure of the drive transistor Q1 including a gate formed in the first wiring layer 33, a source and a drain formed in the second wiring layer 35, and a channel region formed in the semiconductor layer 42, but other transistors are also arranged in these layers 33, 35, and 42, and are connected to the first wiring layer 33 by contacts (not illustrated).

On the first insulating layer 32, the second insulating layer 34 is arranged so as to cover the transistor and the like. The second insulating layer 34 has, for example, a layered structure of a silicon oxide layer, a silicon nitride layer, and a silicon oxide layer having excellent visible light transmittance. A trench 34a is formed in a part of the second insulating layer 34, and the second wiring layer (M2) 35 connected to a source, a drain, and the like of each transistor is formed by filling a contact member 35a in the trench 34a. FIG. 9 illustrates the second wiring layer 35 for connection of the drive transistor Q1 and the anode electrode 12a of the OLED 5, but the second wiring layer connected to other circuit elements is also arranged in the same layer. Furthermore, as described later, a third wiring layer (not illustrated in FIG. 9) may be provided between the second wiring layer 35 and the anode electrode 12a. The third wiring layer can be used as wiring in the pixel circuit, and may also be used for connection with the anode electrode 12a.

On the second insulating layer 34, the third insulating layer 36 that covers the second wiring layer to planarize a surface is arranged. The third insulating layer 36 is formed by a resin material such as an acrylic resin. A film thickness of the third insulating layer 36 is made larger than a film thicknesses of the first to second insulating layers 32 and 34.

A trench 36a is formed on a part of an upper surface of the third insulating layer 36, a contact member 36b is filled in the trench 36a to achieve conduction with the second wiring layer 35, and the anode electrode layer 38 is formed by extending the contact member 36b to the upper surface side of the third insulating layer 36. The anode electrode layer 38 has a layered structure, and includes a metal material layer. The metal material layer generally has low visible light transmittance, and functions as a reflective layer that reflects light. As a specific metal material, for example, AlNd or Ag can be applied.

Since a lowermost layer of the anode electrode layer 38 is a portion in contact with the trench 36a and is easily disconnected, at least a corner portion of the trench 36a may be formed by a metal material such as AlNd, for example. An uppermost layer of the anode electrode layer 38 is formed by a transparent conductive layer such as indium tin oxide (ITO). Alternatively, the anode electrode layer 38 may have, for example, a layered structure of ITO/Ag/ITO. Ag is originally opaque, but the visible light transmittance is improved by reducing a film thickness. While strength is weakened when Ag is thinned, the anode electrode layer 38 can be made function as a transparent conductive layer by having the layered structure with ITO arranged on both surfaces.

On the third insulating layer 36, the fourth insulating layer 37 is arranged so as to cover the anode electrode layer 38. Similarly to the third insulating layer 36, the fourth insulating layer 37 is also formed by a resin material such as an acrylic resin. The fourth insulating layer 37 is patterned in accordance with an arrangement location of the OLED 5, and a recess 37a is formed.

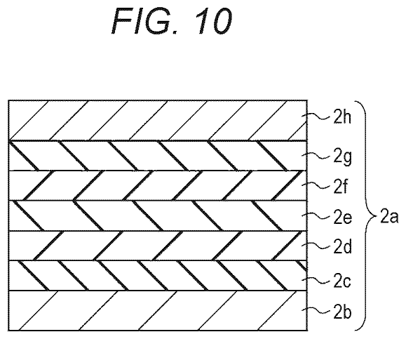

The display layer 2a is arranged so as to include a bottom surface and a side surface of the recess 37a of the fourth insulating layer 37. The display layer 2a has, for example, a layered structure as illustrated in FIG. 10. The display layer 2a illustrated in FIG. 10 has a layered structure in which an anode 2b, a hole injection layer 2c, a hole transport layer 2d, a light-emitting layer 2e, an electron transport layer 2f, an electron injection layer 2g, and a cathode 2h are arranged in a layering order from the anode electrode layer 38 side. The anode 2b is also referred to as the anode electrode 12a. The hole injection layer 2c is a layer into which positive holes from the anode electrode 12a are injected. 0 The hole transport layer 2d is a layer that efficiently transports positive holes to the light-emitting layer 2e. The light-emitting layer 2e recombines positive holes and electrons to generate excitons, and emits light when the excitons return to a ground state. The cathode 2h is also referred to as cathode electrode. The electron injection layer 2g is a layer into which electrons from the cathode 2h are injected. The electron transport layer 2f is a layer that efficiently transports electrons to the light-emitting layer 2e. The light-emitting layer 2e contains an organic substance.

The cathode electrode layer 39 is arranged on the display layer 2a illustrated in FIG. 9. The cathode electrode layer 39 is formed by a transparent conductive layer similarly to the anode electrode layer 38. Note that the transparent conductive layer of the anode electrode layer 38 includes, for example, ITO/Ag/ITO, and the transparent electrode layer of the cathode electrode layer 39 includes, for example, MgAg.

The fifth insulating layer 40 is arranged on the cathode electrode layer 39. The fifth insulating layer planarizes an upper surface and is formed by an insulating material excellent in moisture resistance. The second transparent substrate 41 is arranged on the fifth insulating layer 40.

As illustrated in FIGS. 8 and 9, in the second pixel region 8, the anode electrode layer 38 functioning as a reflective film is arranged almost all over the color pixel 7, and visible light cannot be transmitted accordingly.

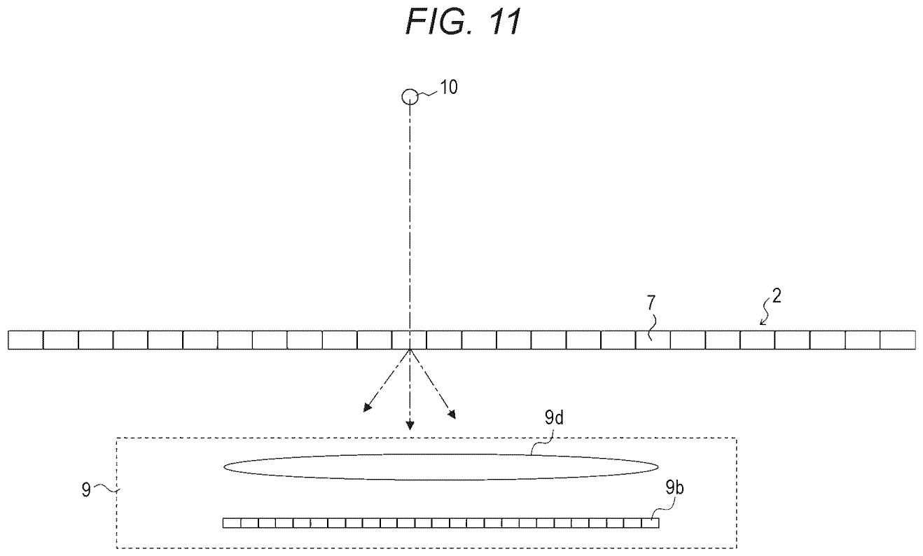

FIG. 11 is a diagram illustrating a diffraction phenomenon that generates diffracted light. Parallel light such as sunlight and highly directional light is diffracted at a boundary between the non-light emitting region 6c and the first light emitting region 6b, and generates high-order diffracted light including the first-order diffracted light. Note that the 0th-order diffracted light is light traveling in the optical axis direction of the incident light, and is light having the highest light intensity in the diffracted light. That is, the 0th-order diffracted light is an imaging object itself and is light to be imaged. Higher-order diffracted light travels in a direction further away from the 0th-order diffracted light, and its light intensity also decreases. In general, the high-order diffracted light including the first-order diffracted light is collectively referred to as diffracted light. The diffracted light is light that is not originally contained in the subject light, and is unnecessary light for imaging the subject 10.

In a captured image with the diffracted light, the brightest spot is the 0th-order light, and the high-order diffracted light spreads from the 0th-order diffracted light in a cross pattern. In a case where the subject light is white light, the diffraction angle differs for each of a plurality of wavelength components contained in the white light, rainbow-colored diffracted light f is generated.

Examples of the pattern of the diffracted light appearing in the captured image include a cross pattern, but what pattern of the diffracted light f is generated depends on a shape of a portion through which the light is transmitted into the non-light emitting region 6c as described later, and if the shape of the portion through which the light is transmitted is known, the pattern of the diffracted light can be predicted by means of simulation based on the diffraction principle. In the planar layout of each pixel 7 in the first pixel region 6 illustrated in FIG. 11, a light transmitting region further exists outside the non-light emitting region 6c, in a gap of the wiring, and around the first light emitting region 6b. As described above, when light transmitting regions with irregular shapes exist at a plurality of locations in the pixel 7, the incident light is complicatedly diffracted, and the pattern of the diffracted light f also becomes complicated.

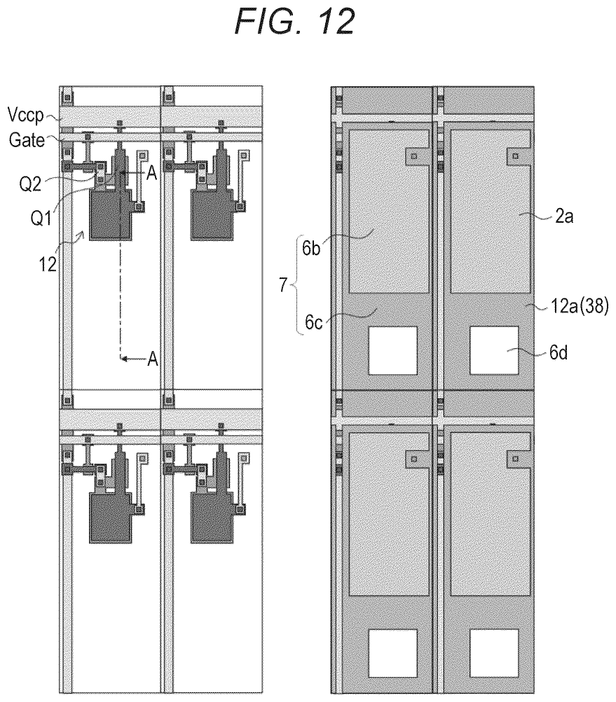

FIG. 12 is a planar layout diagram of an image display device 1 according to an embodiment that solves a problem that may occur in the planar layout in FIG. 11. In FIG. 12, the anode electrode 12a is arranged all over the first light emitting region 6b in the first pixel region 6 so as to prevent light from being transmitted, and the transmissive window 6d having a predetermined shape is provided in the non-light emitting region 6c so as to allow only the inside of the transmissive window 6d to transmit the subject light. FIG. 12 illustrates an example in which the periphery of the transmissive window 6d of the non-light emitting region 6c is covered with the anode electrode 12a, but as described later, a member that defines the shape of the transmissive window 6d is not necessarily limited to the anode electrode 12a.

In FIG. 12, the transmissive window 6d has a rectangular planar shape. The planar shape of the transmissive window 6d is desirably as simple as possible. The simpler the shape, the simpler the generation direction of the diffracted light f, and the diffracted light pattern can be obtained in advance by means of simulation.

As described above, in the present embodiment, in the first pixel region 6 in the display panel 2 located immediately above the sensor 5, as illustrated in FIG. 12, the transmissive window 6d is provided in the non-light emitting region 6c in the pixel 7 to regulate the pattern of the diffracted light f. On the other hand, the second pixel region 8 in the display panel 2 that is not located immediately above the sensor 5 may have a planar layout similar to the planar layout in FIG. 8.

The shape of the transmissive window 6d of the non-light emitting region 6c can be defined by an end of the anode electrode 12a or an end of the wiring layer. It is therefore possible to form the transmissive window 6d having a desired shape and size in a relatively simple manner.

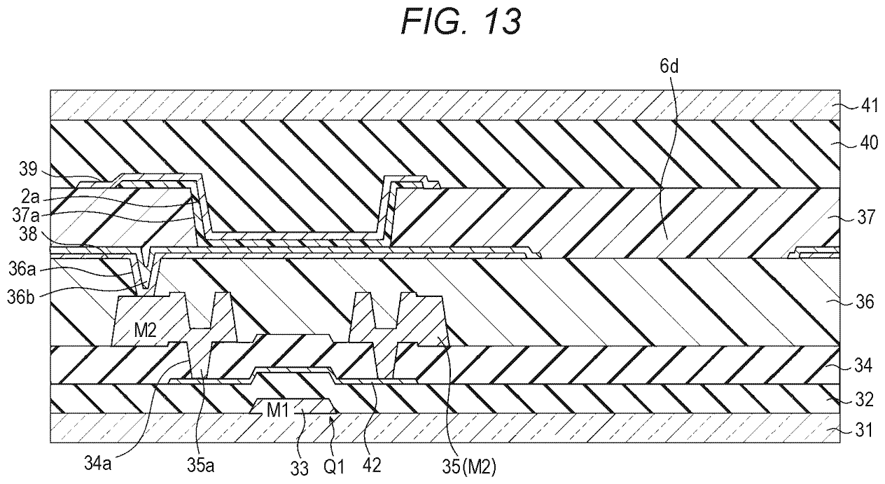

FIG. 13 is a cross-sectional view illustrating a first example of the cross-sectional structure of the first pixel region 6. FIG. 13 illustrates an example in which the shape of the transmissive window 6d in the non-light emitting region 6c is defined by the anode electrode 12a (anode electrode layer 38). An end of the anode electrode layer 38 is formed in a rectangular shape as illustrated in FIG. 14 as the display surface side is viewed from above. As described above, in the example in FIG. 13, the shape of the transmissive window 6d is defined by the end of the anode electrode layer 38.

In the example in FIG. 13, the third insulating layer 36 and the fourth insulating layer 37 inside the transmissive window 6d are left as they are. Therefore, in a case where a material of the third insulating layer 36 and the fourth insulating layer 37 is a colored resin layer, there is a possibility that the visible light transmittance decreases, but at least some of visible light is transmitted, so that the third insulating layer 36 and the fourth insulating layer 37 may be left in the transmissive window 6d.

In the above-described embodiment, the example in which one or more transmissive windows 6d are provided for one pixel 7 (or one color pixel 7) has been described, or alternatively, one or more transmissive windows 6d may be provided for a plurality of pixels 7 (or a plurality of color pixels 7) as a unit.

FIG. 14 is a diagram illustrating an example in which one transmissive window 6d is provided across three pixels 7 (or three color pixels 7). In FIG. 14, for example, the shape of the transmissive window 6d is defined by an end of the second wiring layer (M2) 35. As illustrated in FIG. 14, providing one transmissive window 6d for the plurality of pixels 7 as a unit allows a reduction in the total number of transmissive windows 6d as compared with the case where the transmissive window 6d is provided for each pixel 7, and it is therefore less susceptible to the influence of diffracted light. As will be described later, one aspect of the image display device 1 according to the present disclosure includes two or more transmissive windows having different sizes in the non-light emitting region 6c in the first pixel region 6. The two or more transmissive windows having different sizes may be provided for each pixel, or may be provided across a plurality of pixels as illustrated in FIG. 14.

### (Bright-Line Condition of Diffraction Grating)

Hereinafter, a principle of how diffracted light is generated will be described. As described above, the pixel 7 in the first pixel region 6 includes the non-light emitting region 6c, and the non-light emitting region 6c includes the transmissive window 6d. Since the plurality of pixels 7 is provided in the first pixel region 6, the transmissive windows 6d are provided at regular intervals in the first pixel region 6. It is therefore possible to consider the first pixel region 6 as a diffraction grating in which slits are provided at regular intervals.

FIG. 15 is a diagram for describing a bright-line condition of a diffraction grating 14. FIG. 15 illustrates a state where when parallel light impinges on the diffraction grating 14 along a direction of normal to the diffraction grating 14, the traveling direction of the light is changed by diffraction through slits. In FIG. 15, a diffraction angle is denoted as 0, an interval between the slits is denoted as d, and a distance between the diffraction grating 14 and the screen 15 is denoted as L. Each slit corresponds to the transmissive window 6d, and the distance L corresponds to a distance from the display panel 2 to the image sensor module 9.

The bright-line condition under which rays of light diffracted by the plurality of slits of the diffraction grating 14 intensify each other on the screen 15 is represented by the following Expression (1). Here, λ is a wavelength of the incident light, and m is an integer greater than or equal to 0.

$$d sin λ = m λ \qquad ( 1 )$$

As shown in Expression (1), since the light is intensified at integral multiples of the wavelength of the incident light on the screen 15, bright lines appear at intervals of the integral multiples of the wavelength of the incident light from the center position irradiated with the 0th-order light.

In Expression (1), in a case where the diffraction angle θ is sufficiently small, the following Expression (2) holds. sine θ≈tan θe=x/L . . . (2)

In Expression (2), x denotes the amount of change in the position of the incident light on the screen 15 due to diffraction when the incident light passes through the slit.

When Expression (2) is substituted into Expression (1), the following Expression (3) is obtained.

$$[ Math . 1 ]$$

$$d \frac{x}{L} = m λ \qquad ( 3 )$$

The interval between the bright lines on the screen is represented by the following Expression (4).

$$[ Math . 2 ]$$

$$Δ x = {x}_{m + 1} - {x}_{m} = \frac{L}{d} λ \qquad ( 4 )$$

Expression (4) shows that bright lines appear on the screen 15 at equal intervals Lλ/d.

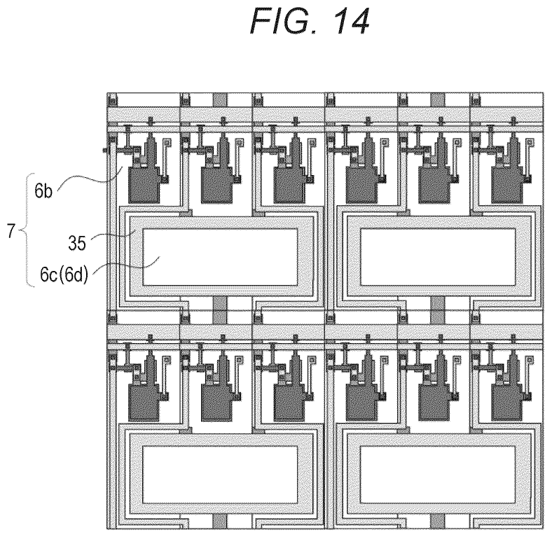

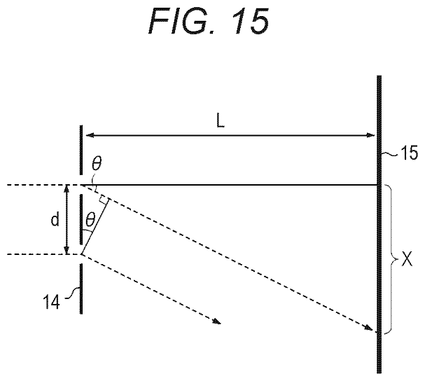

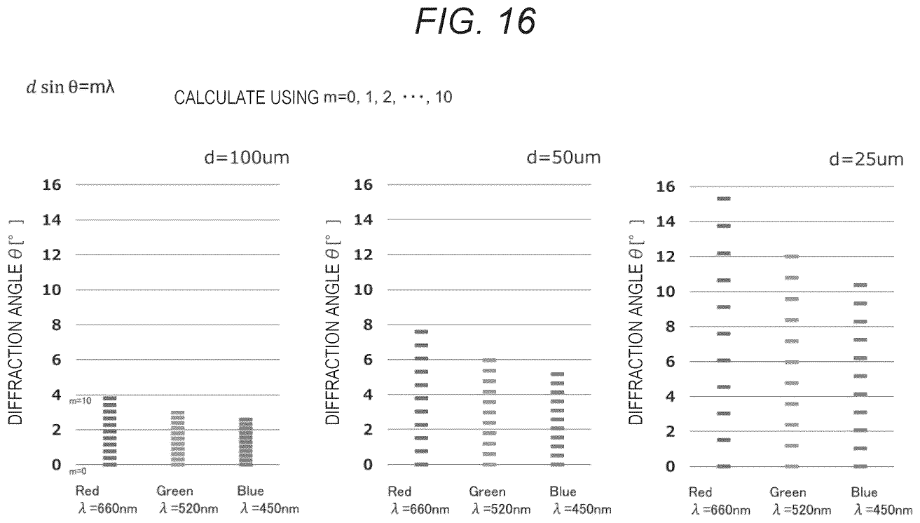

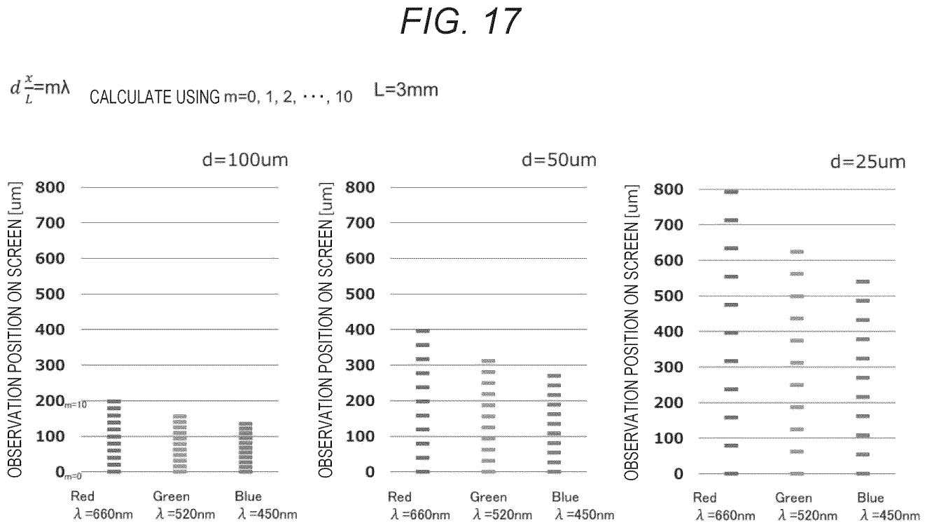

FIGS. 16 and 17 are diagrams illustrating results of simulation of the bright-line condition of the diffraction grating 14. FIG. 16 is a diagram illustrating, in terms of the diffraction angle θ, bright-line conditions of a red light wavelength (λ=660 nm), a green light wavelength (λ=520 nm), and a blue light wavelength (λ=450 nm) for each slit interval (d=100 μm, 50 μm, 25 μm). As illustrated in the drawing, the smaller the interval d between the slits and the larger the wavelength of the incident light, the larger the amount of change of the diffraction angle θ that is the bright-line condition.

FIG. 17 is a diagram illustrating, in terms of the incident light position on the screen 15, bright-line conditions of the red light wavelength (λ=660 nm), the green light wavelength (λ=520 nm), and the blue light wavelength (λ=450 nm) for each slit interval (d=100 μm, 50 μm, 25 μm). As illustrated in the drawing, the smaller the interval d between the slits and the larger the wavelength of the incident light, the larger a difference in the light incident position on the screen that is the bright-line condition.

### (Dark-Line Condition of Single Slit)

Since the slit corresponding to the transmissive window 6d has a width, when a plurality of rays of light passes through one slit (hereinafter, referred to as single slit) and satisfy a predetermined dark-line condition, the amount of light passing through the single slit decreases. The reason why the amount of light decreases is that antiphase light is contained in each ray of light passing through the single slit, so that when all the rays of light passing through the single slit are superimposed on each other, the antiphase rays of light weakens each other.

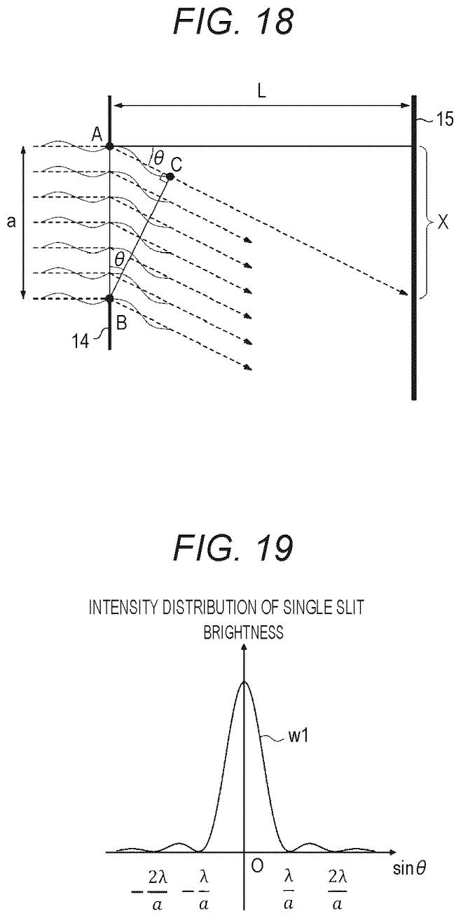

FIG. 18 is a diagram illustrating the dark-line condition of the single slit. As illustrated in the drawing, a plurality of rays of light passes through the single slit. AC in the drawing denotes an optical path difference between a ray of light passing through one end of the slit and a ray of light passing through the other end. When the width of the slit is denoted as a and the light diffraction angle is denoted as θ, the optical path difference AC is represented by a×sin θ. In a case where light for n periods is included in the optical path difference AC, there is a light wave opposite in phase to a light wave having a certain phase, so that when all the light waves are superimposed, the light waves weaken each other as a whole.

Therefore, the dark-line condition corresponds to a case where the following Expression (5) is satisfied. N is an integer greater than or equal to 1. a×sin θ=nλ . . . (5)

FIG. 19 is a diagram illustrating an intensity distribution curve of light passing through the single slit. In FIG. 19, the horizontal axis represents sine, and the vertical axis represents light intensity. As indicated by a curve w1 in FIG. 19, the light intensity of the light passing through the single slit periodically becomes 0 when Expression (5) is satisfied.

In Expression (5), in a case where the diffraction angle θ is small, the relationship of Expression (2) described above holds, and thus the following Expression (6) is obtained by substituting the relationship of Expression (2) into Expression (5).

$$[ Math . 3 ]$$

$$a \frac{x}{L} = n λ \qquad ( 6 )$$

Expression (6) is a condition that rays of light passing through the single slit weaken each other, and is referred to as dark-line condition. When the dark-line condition of the single slit of Expression (6) coincides with the bright-line condition of the diffraction grating 14, the bright line becomes less noticeable. That is, when the dark-line condition is satisfied at the position where the bright line of light appears, the bright line becomes dark and less noticeable. A condition that x satisfying the bright-line condition satisfies the dark-line condition corresponds to a case where the following Expression (7) holds.

$$[ Math . 4 ]$$

$$x = \frac{L}{a} λ = m \frac{L}{d} λ \qquad ( 7 )$$

When Expression (7) is transformed, Expression (8) is obtained.

$$[ Math . 5 ]$$

$$a = \frac{d}{m} \qquad ( 8 )$$

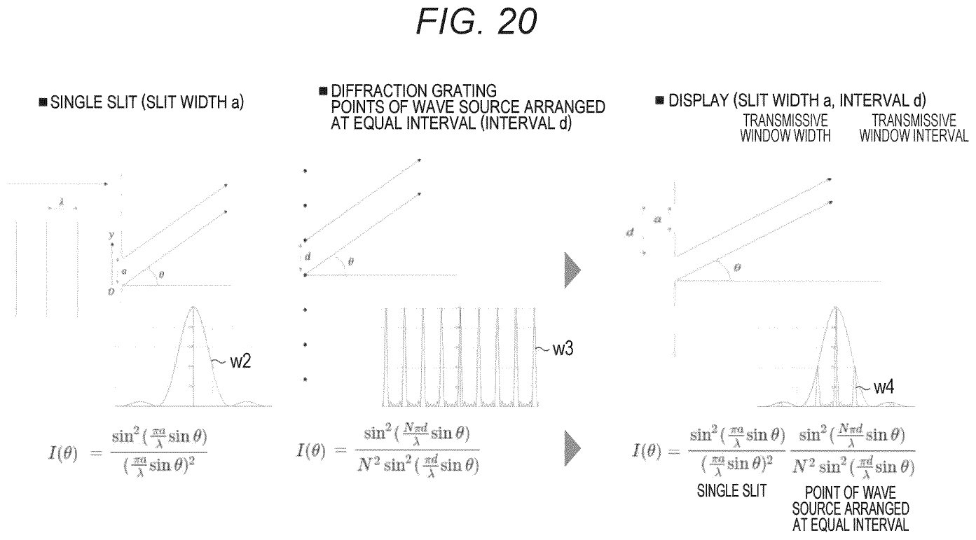

FIG. 20 is a diagram illustrating how to suppress diffracted light in the present embodiment. Light intensity I (θ) of light passing through the single slit corresponding to one transmissive window 6d is calculated by means of Expression (9) and represented by a curve w2.

$$[ Math . 6 ]$$

$$I ( θ ) = \frac{{sin}^{2} ( \frac{π a}{λ} sin θ )}{{( \frac{π a}{λ} sin θ )}^{2}} \qquad ( 9 )$$

Furthermore, the light intensity on the screen 15 in a case where each of the plurality of slits arranged at equal intervals d is regarded as a point of wave source is calculated by means of Expression (10) and represented by a curve w3.

$$[ Math . 7 ]$$

$$I ( θ ) = \frac{{sin}^{2} ( \frac{N π d}{λ} sin θ )}{{N}^{2} {sin}^{2} ( \frac{π d}{λ} sin θ )} \qquad ( 10 )$$

Light intensity I (θ) obtained by multiplying the light intensity I (θ) of Expression (9) by the light intensity I (θ) of Expression (10) is calculated by means of Expression (11) and represented by a curve w4.

$$[ Math . 8 ]$$

$$I ( θ ) = \frac{{sin}^{2} ( \frac{π a}{λ} sin θ )}{{( \frac{π a}{λ} sin θ )}^{2}} \cdot \frac{{sin}^{2} ( \frac{N π d}{λ} sin θ )}{{N}^{2} {sin}^{2} ( \frac{π d}{λ} sin θ )} \qquad ( 11 )$$

As can be seen from the curve w4, the light intensity of the 0th-order light of the diffracted light cannot be suppressed, but the light intensity of the first-order and higher-order light can be suppressed, and in particular, the light intensity of the second-order and higher-order light can be reduced to nearly zero.

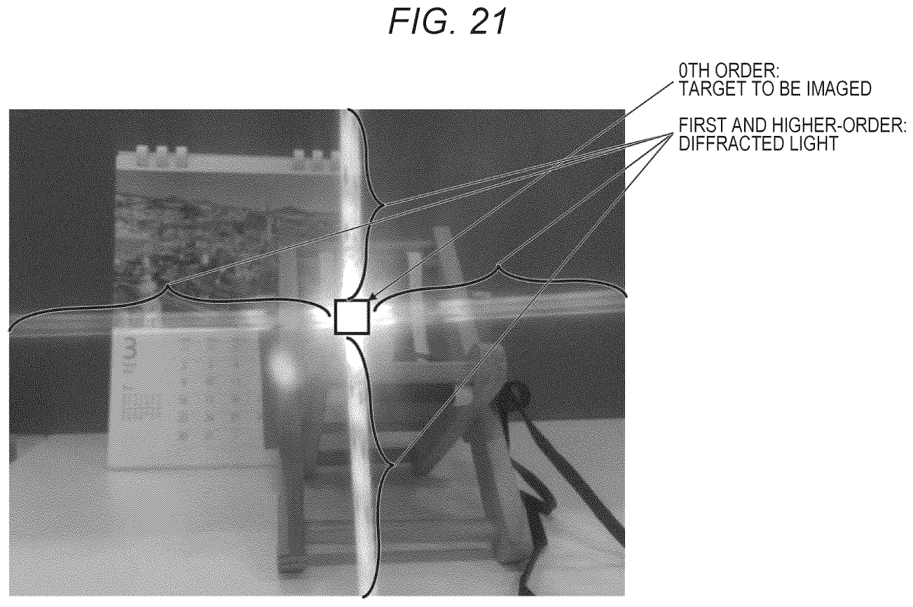

FIG. 21 is a diagram illustrating an example of an image obtained by causing the image sensor module to image the subject light transmitted through the display panel 2, without adopting the diffracted light suppression method according to the present embodiment described above. As illustrated in the drawing, diffracted light appears extending in four directions from the 0th-order light. The diffracted light contains a plurality of rays of high-order light such as the first-order light and the second-order light, and lower-order light has higher light intensity. Furthermore, in a case where the incident light contains a plurality of wavelength components, spacing of the high-order light differs for each wavelength, so that the diffracted light is visually recognized separately for each wavelength (color).

In the present embodiment, the dark-line condition at the position satisfying the bright-line condition is satisfied to cancel the bright line out. Specifically, Expression (8) is satisfied. In Expression (8), it is possible to change the light intensity of the high-order light component of the diffracted light by changing the value of m.

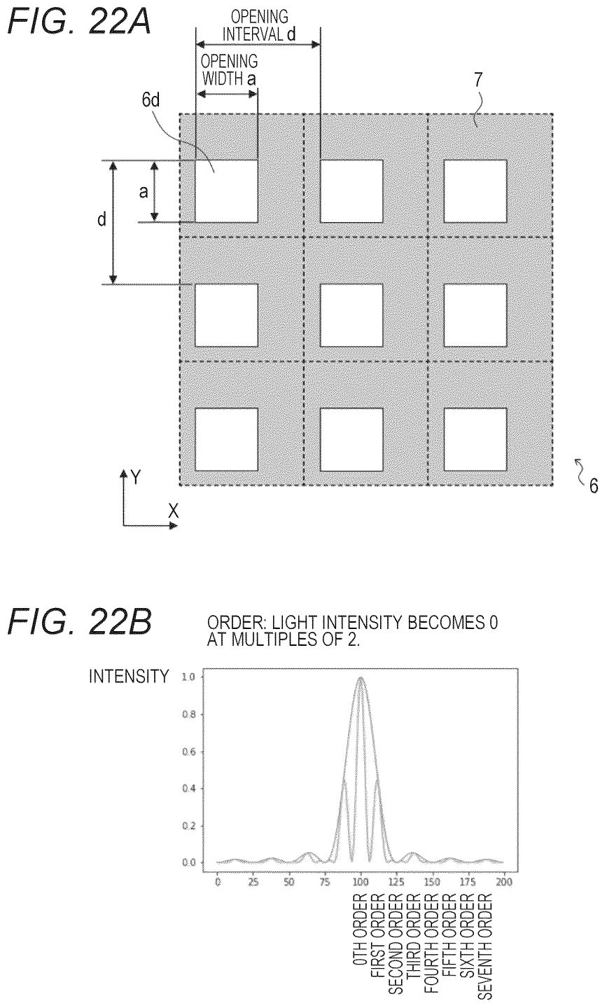

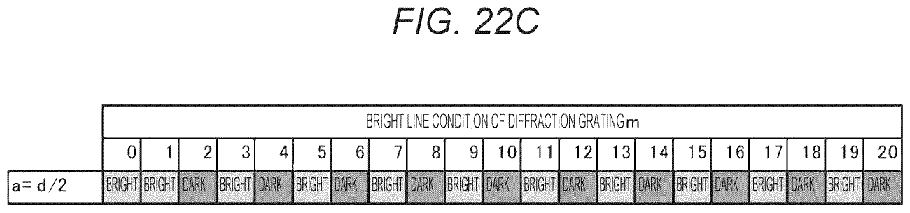

FIG. 22A is a plan view illustrating the width of each transmissive window 6d and the interval (pitch) between the transmissive windows 6d in a case where m=2. As illustrated in FIG. 22A, in both the first direction X and the second direction Y, a ratio of the interval between the transmissive windows 6d to the width of each transmissive window 6d is 2.

FIG. 22B is a diagram illustrating light intensity of diffracted light in a case where m=2. In a case where m=2, as illustrated in FIG. 22B, the 0th-order light component and the first-order light component contained in the diffracted light cannot be canceled out, but the second-order light component can be reduced to nearly zero. Furthermore, the second-order light component and higher-order light components corresponding to integral multiples of 2 can be reduced to nearly zero.

FIG. 22C is a diagram illustrating brightness of high-order light components from the 0th-order light to the 20th-order light contained in the diffracted light. In FIG. 22C, a high-order light component that becomes a bright line is described as “bright”, and a high-order light component that becomes a dark line is described as “dark”. As illustrated in FIG. 22C, in a case where m=2, the second-order light component and higher-order light components corresponding to integral multiples of 2 can be darkened.

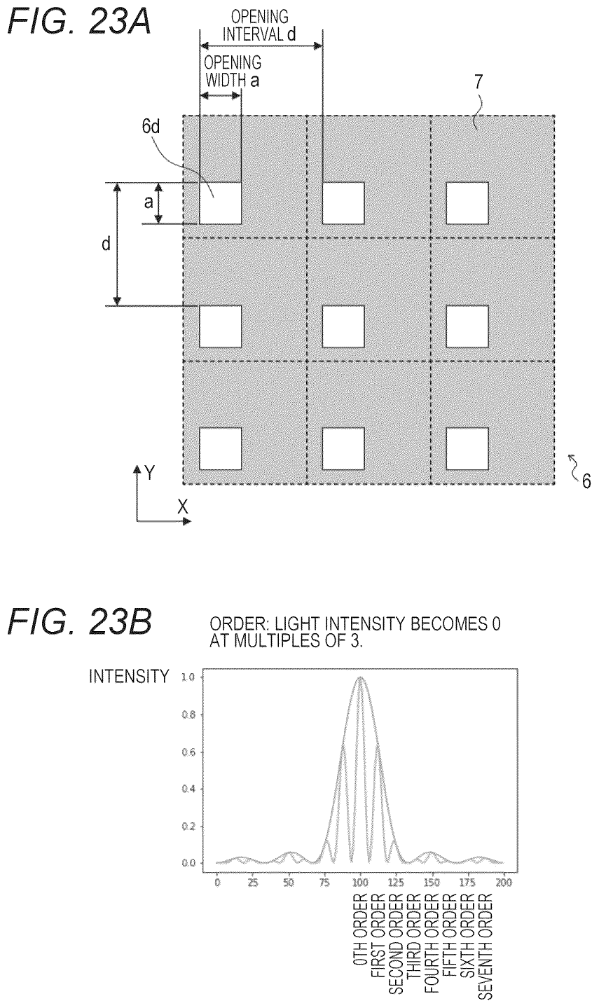

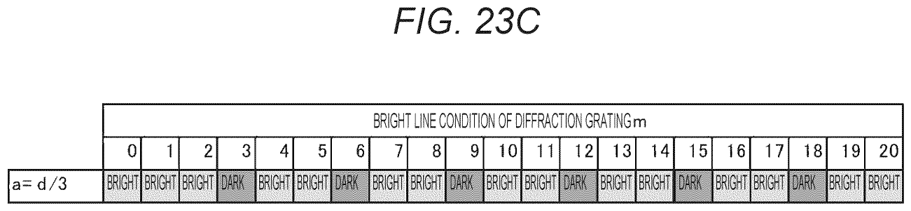

FIG. 23A is a plan view illustrating the width of each transmissive window 6d and the interval (pitch) between the transmissive windows 6d in a case where m=3. As illustrated in FIG. 23A, in both the first direction X and the second direction Y, a ratio of the interval between the transmissive windows 6d to the width of each transmissive window 6d is 3.

FIG. 23B is a diagram illustrating light intensity of diffracted light in a case where m=3. In a case where m=3, as illustrated in FIG. 23B, the 0th-order light component, the first-order light component, and the second-order light component contained in the diffracted light cannot be canceled out, but the third-order light component can be reduced to nearly zero. Furthermore, the third-order light component and higher-order light components corresponding to integral multiples of 3 can be reduced to nearly zero.

FIG. 23C is a diagram illustrating brightness of high-order light components from the 0th-order light to the 20th-order light contained in the diffracted light. In FIG. 23C, a high-order light component that becomes a bright line is described as “bright”, and a high-order light component that becomes a dark line is described as “dark”. As illustrated in FIG. 23C, in a case where m=3, the third-order light component and higher-order light components corresponding to integral multiples of 3 can be darkened.

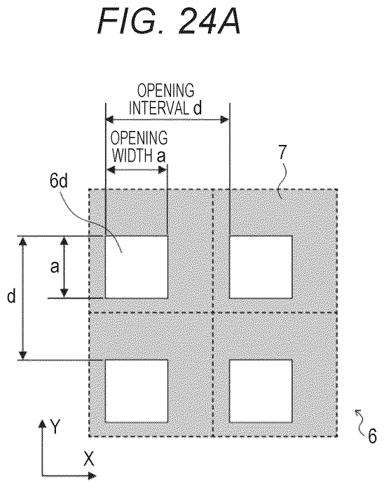

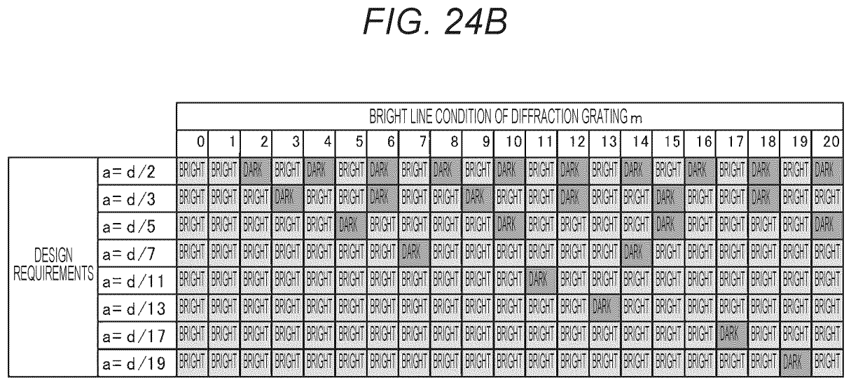

As illustrated in FIGS. 22A to 22C and FIGS. 23A to 23C, among various high-order light components contained in the diffracted light, high-order light components that can be darkened differ in a manner that depends on the value of m. FIG. 24A is a diagram illustrating a relationship between an opening width a of each transmissive window 6d and an opening interval d between the transmissive windows 6d. FIG. 24B is a diagram illustrating brightness or darkness of each high-order light component contained in the diffracted light in a case where m is changed in a plurality of ways. In FIG. 24B, d/a=m is any prime number selected from among 2 to 19.

As illustrated in FIG. 24B, in a case where m=2, as in FIG. 22C, the second-order component and higher-order light components corresponding to multiples of 2 can be darkened. In a case where m=3, as in FIG. 23C, the third-order light component and higher-order light components corresponding to multiples of 3 can be darkened. In a case of m=5, the fifth-order light component and higher-order light components corresponding to multiples of 5 can be darkened. In a case of m=7, the seventh-order light component and higher-order light components corresponding to multiples of 7 can be darkened. In a case of m=11, the 11th-order light component and higher-order light components corresponding to multiples of 11 can be darkened. In a case of m=13, the 13th-order light component and higher-order light components corresponding to multiples of 13 can be darkened. In a case of m=17, the 17th-order light component and higher-order light components corresponding to multiples of 17 can be darkened. In a case of m=19, the 19th-order light component and higher-order light components corresponding to multiples of 19 can be darkened.

As described above, it is possible to darken all the high-order light components from the second-order light to the 20th-order light contained in the diffracted light by using all the prime numbers below 20 as m.

### First Specific Example

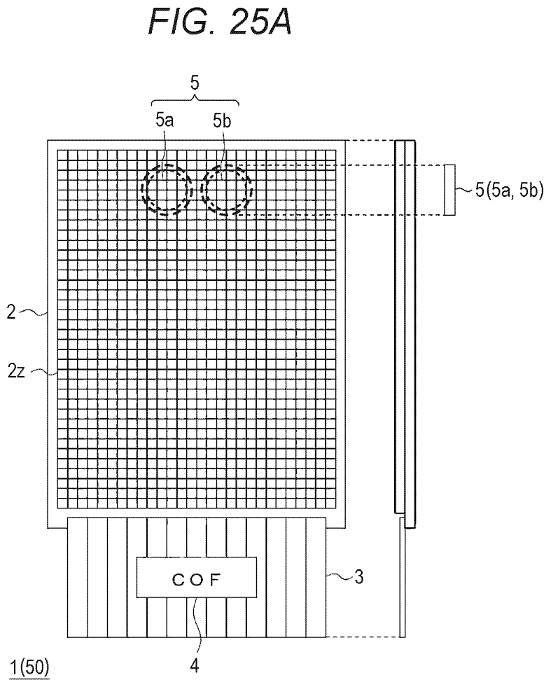

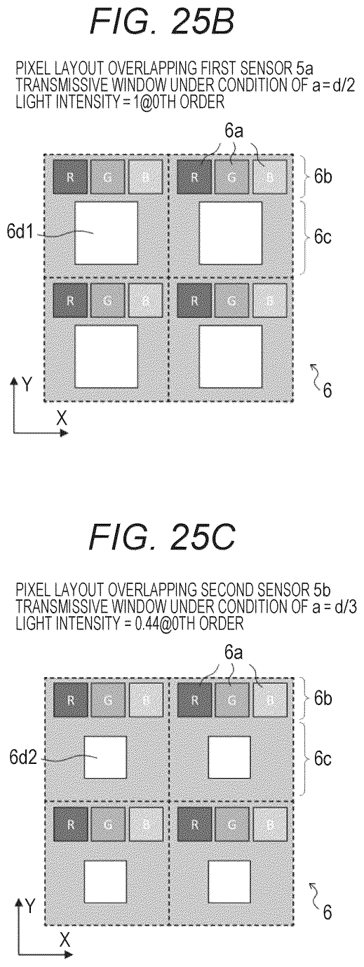

FIGS. 25A, 25B, and 25C are diagrams for describing characteristics of an electronic apparatus 50 including an image display device 1 according to a first specific example. FIG. 25A is a plan view of the electronic apparatus 50, and FIGS. 25B and 25C are plan views of each pixel 7 in a first pixel region 6.

As illustrated in FIG. 25A, the electronic apparatus 50 according to the first specific example includes a display panel 2 and two sensors 5 (5a, 5b) arranged immediately below the display panel 2. The two sensors 5 may be arranged at any locations. The display panel 2 includes the first pixel region 6 arranged in a region overlapping the sensor 5 and a second pixel region 8 arranged in a region not overlapping the sensor 5. Since the electronic apparatus 50 according to the first specific example includes the two sensors 5, two first pixel regions 6 corresponding to the two sensors 5 are provided in the display panel 2. The two sensors 5 each have the function of the image sensor module 9, and image subject light incident through a corresponding one of the first pixel regions 6 in the display panel 2.

As illustrated in FIGS. 25B and 25 C, each pixel in the first pixel region 6 includes a first self light-emitting element 6a, a first light emitting region 6b, and a non-light emitting region 6c. The non-light emitting region 6c includes a transmissive window 6d. In their respective non-light emitting regions 6c included in the two first pixel regions 6, transmissive windows 6d having different sizes are provided. Hereinafter, the two transmissive windows 6d having different sizes are referred to as first transmissive window 6d1 and second transmissive window 6d2. Furthermore, the two sensors 5 are referred to as first sensor 5a and second sensor 5b. The first transmissive window 6d1 and the second transmissive window 6d2 are similar in shape to each other.

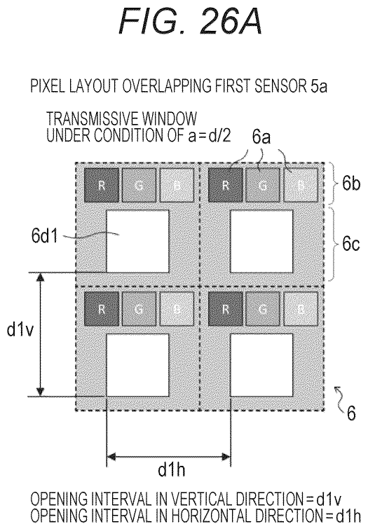

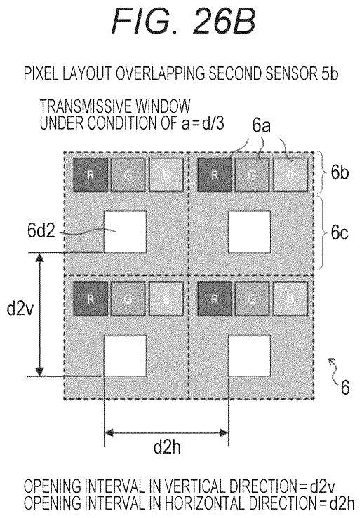

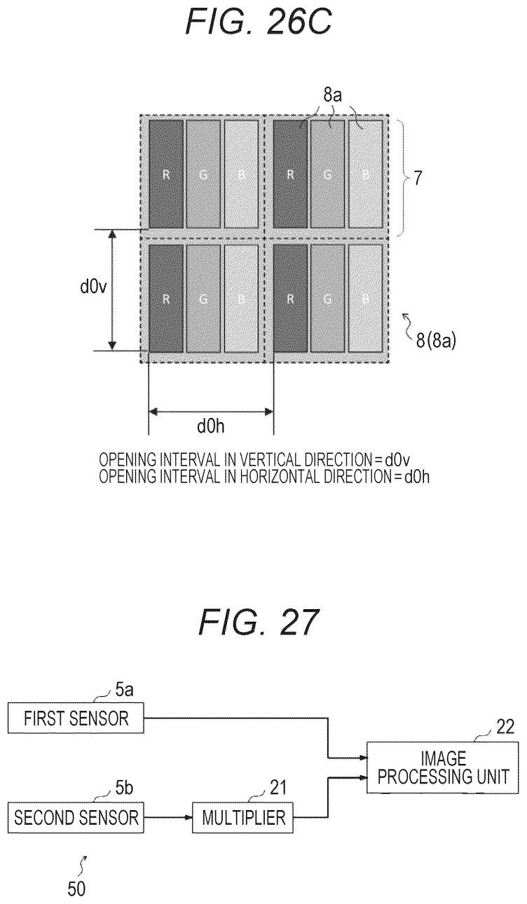

As illustrated in FIG. 26A, the first transmissive window 6d1 in the first pixel region 6 arranged at a position overlapping the first sensor 5a has the opening interval d to the opening width a of 2 in both the first direction X and the second direction Y. Similarly, as illustrated in FIG. 26B, the second transmissive window 6d2 in the first pixel region 6 arranged at a position overlapping the second sensor 5b has the opening interval d to the opening width a of 3 in both the first direction X and the second direction Y.

FIG. 26C is a diagram illustrating a structure of the pixel 7 in the second pixel region 8 arranged at a position not overlapping the sensor 5. Each pixel 7 in the second pixel region 8 includes a second self light-emitting element 8a and a second light emitting region 8b arranged almost all over the pixel 7, but is not provided with the transmissive window 6d.

The transmissive window 6d (hereinafter, referred to as first transmissive window 6d1) in the non-light emitting region 6c in the first pixel region 6 arranged at a position overlapping the first sensor 5a satisfies a relationship of a=d/2, and the transmissive window 6d (hereinafter, referred to as second transmissive window 6d2) in the non-light emitting region 6c in the first pixel region 6 arranged at a position overlapping the second sensor 5b satisfies a relationship of a=d/3. Therefore, an area of the first transmissive window 6d1 is (3/2)×(3/2)=2.25 times an area of the second transmissive window 6d2.

The first sensor 5a images the subject light transmitted through the first transmissive window 6d1. The second sensor 5b images the subject light transmitted through the second transmissive window 6d2. Since the first transmissive window 6d1 is larger in area than the second transmissive window 6d2, the image captured by the first sensor 5a is brighter than the image captured by the second sensor 5b. Therefore, in order to adjust brightness, it is necessary to multiply image data output from the second sensor 5b by 2.25.

In the image captured by the first sensor 5a, as illustrated in FIGS. 22C and 24B, the second-order light component and higher-order light component corresponding to multiples of 2 contained in the diffracted light becomes dark. On the other hand, in the image captured by the second sensor 5b, as illustrated in FIGS. 23C and 24B, the third-order light component and higher-order light components corresponding to multiples of 3 contained in the diffracted light become dark.

The electronic apparatus 50 according to the first specific example generates final image data on the basis of the image data output from the first sensor 5a and the image data obtained by multiplying the image data output from the second sensor 5b by 2.25.

As described above, the first pixel region 6 arranged at a position overlapping the first sensor 5a includes a first pixel group in which a plurality of pixels (hereinafter, referred to as first pixel) is two-dimensionally arranged, and the first pixel 4 region 6 arranged at a position overlapping the second sensor 5b includes a second pixel group in which a plurality of pixels (hereinafter, referred to as second pixel) is two-dimensionally arranged. The first pixel and the second pixel each include the first self light-emitting element 6a, the first light emitting region 6b, and the non-light emitting region 6c. For example, the transmissive window 6d (first transmissive window 6d1) of the non-light emitting region 6c in the first pixel is made larger in size than the transmissive window 6d (second transmissive window 6d2) of the non-light emitting region 6c in the second pixel.

A ratio of the interval between the transmissive windows to the width of each transmissive window in the first pixel group is a first prime number, and a ratio of the interval between the transmissive windows to the width of each transmissive windows in the second pixel group is a second prime number different from the first prime number. The use of the first prime number and the second prime number makes it possible to suppress high-order light components corresponding to multiples of the first prime number and high-order light components corresponding to multiples of the second prime number contained in the diffracted light.

The plurality of first pixels in the first pixel group is arranged in multiple rows and columns in the first direction and the second direction, and the plurality of second pixels in the second pixel group is arranged in multiple rows and columns in the first direction and the second direction. A ratio of the interval between the transmissive windows in the first pixel group to the width of each transmissive windows in the first direction is equal to a ratio of the interval between the transmissive windows in the first pixel group to the width of each transmissive window in the second direction. Furthermore, a ratio of the interval between the transmissive windows in the second pixel group to the width of each transmissive window in the first direction is equal to a ratio of the interval between the transmissive windows in the second pixel group to the width of each transmissive window in the second direction. One of the first prime number or the second prime number may be 2, and the other may be 3, or may be another prime number value.

Furthermore, three or more transmissive windows having different sizes may be provided in the non-light emitting region 6c. In this case, ratios of intervals of the three or more transmissive windows to the widths of the three or more transmissive windows are different prime numbers.

FIG. 27 is a block diagram related to image processing that is performed by the electronic apparatus 50 according to the first specific example. Note that the electronic apparatus 50 may perform various functions other than the generation of image data, but FIG. 27 illustrates only a block configuration related to the generation of image data.

As illustrated in FIG. 27, the electronic apparatus 50 according to the first specific example includes the first sensor 5a, the second sensor 5b, a multiplier 21 that multiplies image data output from the second sensor 5b by 2.25, and an image processing unit 22.

The image processing unit 22 generates image data in which diffracted light is suppressed on the basis of the image data output from the first sensor 5a and image data obtained by multiplying the image data output from the second sensor 5b by 2.25. For example, the image processing unit 22 may generate image data obtained by averaging the image data output from the first sensor 5a and the image data output from the second sensor 5b for each pixel. Alternatively, image data in which the second-order light component and higher-order light components corresponding to multiples of 2 of the diffracted light are suppressed on the basis of the image data output from the first sensor 5a and image data in which the third-order light component and higher-order light components corresponding to multiples of 3 of the diffracted light are suppressed on the basis of the image data output from the second sensor 5b may be generated.

As described above, in the first specific example, the transmissive windows 6d having different sizes are provided in association with the two sensors 5, and the two pieces of image data captured by the two sensors 5 are combined, so that the image data in which the high-order light components of the diffracted light are suppressed can be generated.

The first specific example focuses on the fact that the high-order light components of the diffracted light contained in the image data captured by the sensor 5 differ in a manner that depends on the size of the transmissive window 6d. It is possible to extract and remove, by combining the two pieces of image data captured by the two sensors 5, the high-order light components of the diffracted light, and in the image data finally obtained, the second-order and higher order light components of the diffracted light are reduced.

### Second Specific Example

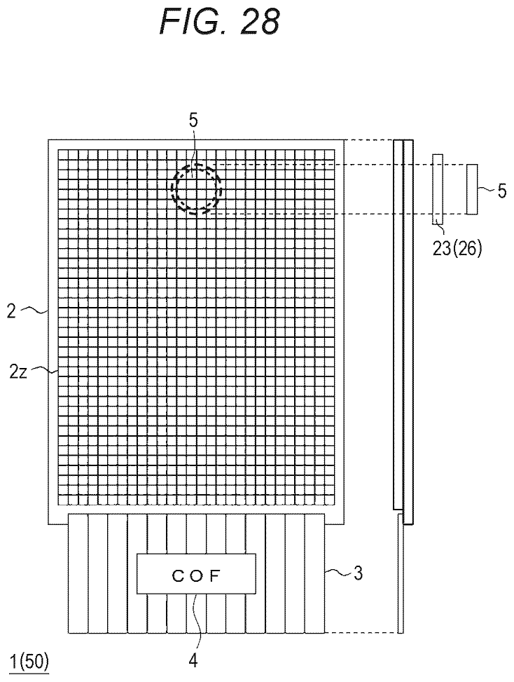

FIG. 28 is a schematic plan view and a cross-sectional view of an electronic apparatus 50 including an image display device 1 according to a second specific example. The electronic apparatus 50 according to the second specific example includes a display panel 2, a light regulating member 23 arranged immediately below the display panel 2, and a sensor 5 arranged immediately below the light regulating member 23.

It is only required that at least one sensor 5 be provided, and FIG. 28 illustrates an example in which one sensor 5 is provided. The sensor 5 has the function of the image sensor module 9.

The display panel 2 includes a first pixel region 6 arranged in a region overlapping the sensor 5 and a second pixel region 8 arranged in a region not overlapping the sensor 5.

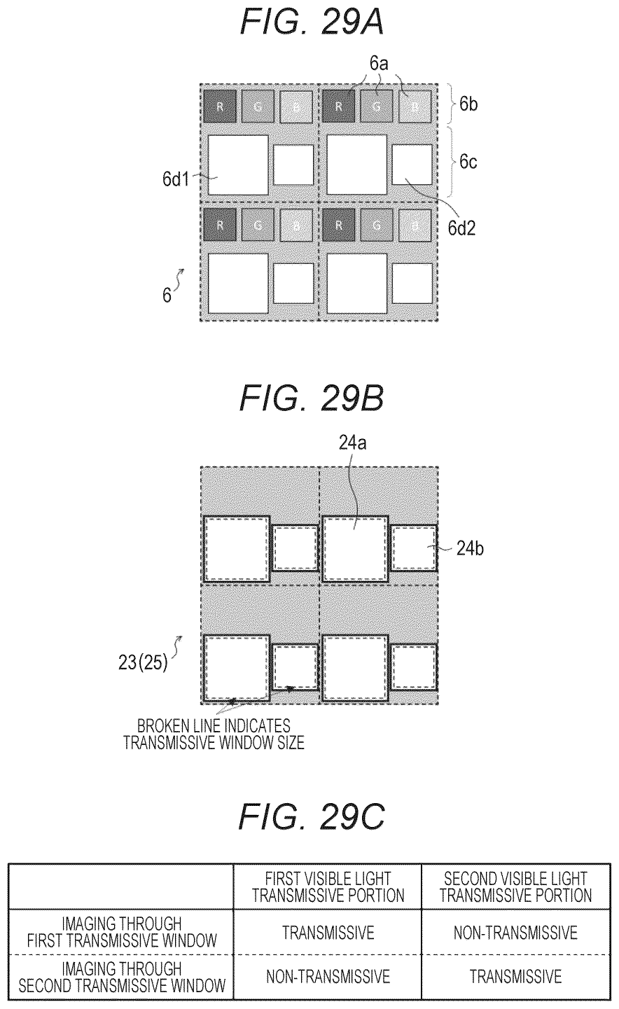

FIG. 29A is a plan view illustrating pixels in the first pixel region 6 arranged in a region overlapping the sensor 5 in the display panel 2. The sensor 5 images subject light transmitted through the first pixel region 6 in the display panel 2. Each pixel in the first pixel region 6 includes a first self light-emitting element 6a, a first light emitting region 6b, and a non-light emitting region 6c. Each non-light emitting region 6c includes a plurality of transmissive windows 6d having different sizes. The non-light emitting region 6c is arranged so as to cause the subject light transmitted through the transmissive windows 6d to impinge on the sensor 5 as the display surface side of the display panel 2 is viewed from above. Although FIG. 29A illustrates an example in which two transmissive windows 6d having different sizes are provided in the non-light emitting region 6c, three or more transmissive windows 6d having different sizes may be provided. Hereinafter, the two transmissive windows 6d in FIG. 29A are referred to as first transmissive window 6d1 and second transmissive window 6d2. The first transmissive window 6d1 is larger in size than the second transmissive window 6d2.

FIG. 29B is a plan view of the light regulating member 23. As illustrated in the cross-sectional view of FIG. 28, the light regulating member 23 is arranged between the display panel 2 and the sensor 5. That is, the light regulating member 23 is arranged over a surface side opposite to the display surface of the display panel 2, and arranged so as to overlap the display panel 2 as viewed from above. The light regulating member 23 selectively generates any one of two or more visible light transmissive portions 24a and 24b having different sizes at positions overlapping the transmissive windows 6d as viewed from above. The size of each of the visible light transmissive portions 24a and 24b is smaller than or equal to the size of a corresponding one of the transmissive windows 6d in the non-light emitting region 6c.

As described above, the non-light emitting region 6c included in each pixel in the first pixel region 6 includes the plurality of transmissive windows 6d (6d1, 6d2) having different sizes. The light regulating member 23 can selectively generate the plurality of visible light transmissive portions 24a and 24b different in position and size in accordance with the positions and sizes of the transmissive windows 6d1 and 6d2.

FIG. 29B illustrates an example in which two visible light transmissive portions 24a and 24b having different sizes can be generated in the light regulating member 23 in association with the two transmissive windows 6d1 and 6d2 in FIG. 29A. Hereinafter, the two transmissive windows 6d are referred to as first transmissive window 6d1 and second transmissive window 6d2, and the two visible light transmissive portions 24a and 24b are referred to as first visible light transmissive portion 24a and second visible light transmissive portion 24b. Subject light transmitted through the first transmissive window 6d1 is transmitted through the first visible light transmissive portion 24a, and subject light transmitted through the second transmissive window 6d2 is transmitted through the second visible light transmissive portion 24b. The size of the first visible light transmissive portion 24a is larger than or equal to the size of the first transmissive window 6d1, and the first transmissive window 6d1 falls within a range of the first visible light transmissive portion 24a as viewed from above. Similarly, the size of the second visible light transmissive portion 24b is larger than or equal to the size of the second transmissive window 6d2, and the second transmissive window 6d2 falls within a range of the second visible light transmissive portion 24b as viewed from above.

The light regulating member 23 can vary the sizes of the visible light transmissive portions 24a and 24b as necessary. The light regulating member 23 selectively generates any one of the plurality of transmissive windows 6d under electrical control or mechanical control.

The light regulating member 23 is, for example, a liquid crystal shutter 25 capable of electrically controlling to vary visible light transmittance. The use the liquid crystal shutter 25 as the light regulating member 23 allows the transmittance of the region corresponding to the plurality of transmissive windows 6d in the non-light emitting region 6c to be variable. The liquid crystal shutter 25 can vary the visible light transmittance by switching a voltage applied between electrodes arranged on both sides of a liquid crystal layer. It is possible to selectively generate, by arranging a plurality of electrodes in the liquid crystal shutter 25 in accordance with the positions of the two transmissive windows 6d (the first transmissive window 6d1 and the second transmissive window 6d2) in the non-light emitting region 6c and switching a voltage applied to such electrodes, any one of the first visible light transmissive portion 24a corresponding to the first transmissive window 6d1 or the second visible light transmissive portion 24b corresponding to the second transmissive window 6d2.

FIG. 29C is a diagram illustrating a switching operation of the liquid crystal shutter 25. In a case where the subject light transmitted through the first transmissive window 6d1 in the first pixel region 6 is imaged, the liquid crystal shutter 25 generates the first visible light transmissive portion 24a and does not generate the second visible light transmissive portion 24b. That is, the first visible light transmissive portion 24a is brought into a transmissive state, and the second visible light transmissive portion 24b is brought into a non-transmissive state. On the other hand, in a case where the subject light transmitted through the second transmissive window 6d2 in the first pixel region 6 is imaged, the liquid crystal shutter 25 generates the second visible light transmissive portion 24b and does not generate the first visible light transmissive portion 24a. That is, the second visible light transmissive portion 24b is brought into the transmissive state, and the first visible light transmissive portion 24a is brought into the non-transmissive state.

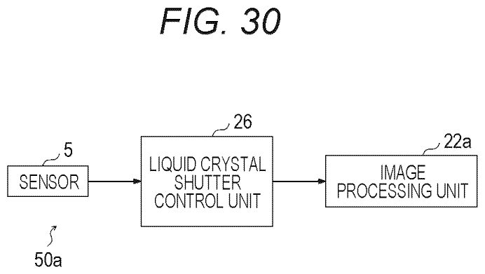

FIG. 30 is a block diagram related to image processing that is performed by the electronic apparatus 50 according to the second specific example. As illustrated in FIG. 30, the electronic apparatus 50 according to the second specific example includes the sensor 5, a liquid crystal shutter control unit 26, and an image processing unit 22a.

The liquid crystal shutter control unit 26 alternately selects and generates any one of the first visible light transmissive portion 24a or the second visible light transmissive portion 24b by controlling the voltage applied to the plurality of electrodes in the liquid crystal shutter 25.

FIG. 29A illustrates the example in which the non-light emitting region 6c includes two transmissive portions having different sizes is provided for each pixel in the first pixel region 6 in the display panel 2, but the transmissive window 6d may be provided almost all over the non-light emitting region 6c.

In this case, in a state where the first visible light transmissive portion 24a is generated in the liquid crystal shutter 25, the sensor 5 images the subject light transmitted through the transmissive window 6d arranged almost all over the non-light emitting region 6c in the display panel 2 and the first visible light transmissive portion 24a, and outputs first image data. Next, in a state where the second visible light transmissive portion 24b is generated in the liquid crystal shutter 25, the sensor 5 images the subject light transmitted through the transmissive window 6d arranged almost all over the non-light emitting region 6c in the display panel 2 and the second visible light transmissive portion 24b, and outputs second image data.

The image processing unit 22a generates, on the basis of the first image data and the second image data, image data in which high-order light components of diffracted light are suppressed or cancelled out.

In FIG. 29A, the plurality of transmissive windows 6d having different sizes is provided in the non-light emitting region 6c in the first pixel region 6 of the display panel 2, but regardless of the sizes of the transmissive windows 6d in the non-light emitting region 6c, the subject light incident on the sensor 5 is restricted by the size of the visible light transmissive window 6d generated in the liquid crystal shutter 25. The plurality of transmissive windows 6d, therefore, need not necessarily be provided in the non-light emitting region 6c.

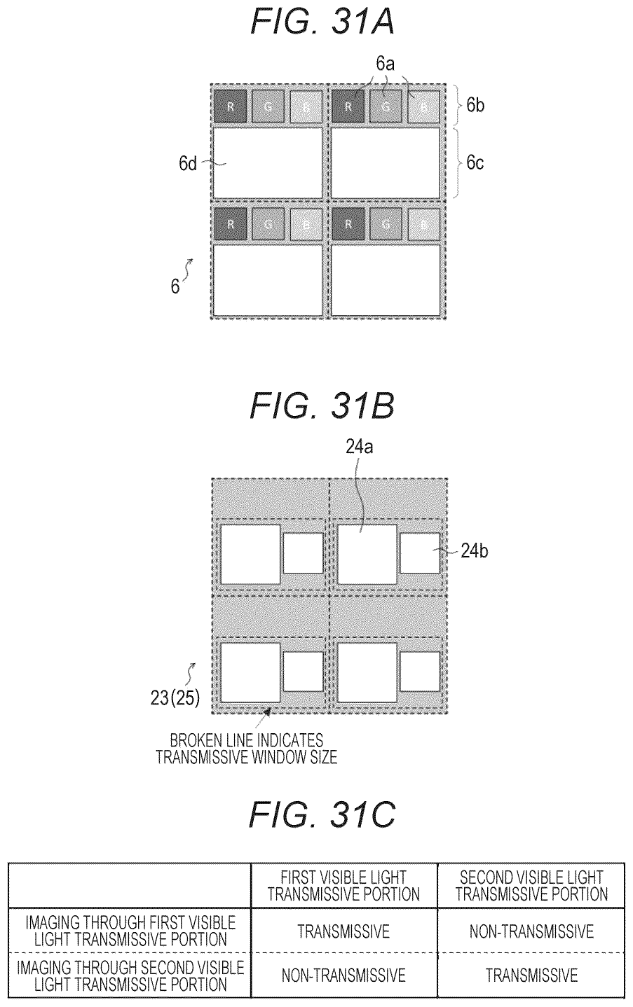

FIG. 31A is a modification of FIG. 29A, and is a plan view illustrating pixels in the first pixel region 6 arranged in a region overlapping the sensor 5 in the display panel 2. FIG. 31B is a plan view of the liquid crystal shutter 25 corresponding to FIG. 31A.

As illustrated in FIG. 31A, the transmissive window 6d is arranged almost all over the non-light emitting region 6c. Therefore, the subject light incident on the first pixel region 6 of the display panel 2 is transmitted through almost all over the non-light emitting region 6c and impinges on the liquid crystal shutter 25.

The liquid crystal shutter 25 can selectively generate any one of the plurality of visible light transmissive portions 24a and 24b having different sizes. FIG. 31B illustrates an example in which any one of the first visible light transmissive portion 24a or the second visible light transmissive portion 24b, the first visible light transmissive portion 24a and the second visible light transmissive portion 24b having different sizes, is selectively generated. The subject light transmitted through almost all over the non-light emitting region 6c in the first pixel region 6 of the display panel 2 is transmitted through the first visible light transmissive portion 24a or the second visible light transmissive portion 24b and impinges on the sensor 5.

As illustrated in FIGS. 31A and 31B, even if the transmissive window 6d is arranged almost all over the non-light emitting region 6c in the display panel 2, only the subject light transmitted through the first visible light transmissive portion 24a or the second visible light transmissive portion 24b of the liquid crystal shutter 25 impinges on the sensor 5. This eliminates the need of providing the plurality of transmissive windows 6d having different sizes in the non-light emitting region 6c in the liquid crystal panel, and it is therefore possible to manufacture the display panel 2 in a simple manner.

FIG. 31C is a diagram illustrating a switching operation of the liquid crystal shutter 25. In a case where the subject light transmitted through the first visible light transmissive portion 24a of the liquid crystal shutter 25 is imaged, the first visible light transmissive portion 24a is generated and the second visible light transmissive portion 24b is not generated. That is, the first visible light transmissive portion 24a is brought into the transmissive state, and the second visible light transmissive portion 24b is brought into the non-transmissive state. On the other hand, in a case where the subject light transmitted through the second visible light transmissive portion 24b of the liquid crystal shutter 25 is imaged, the second visible light transmissive portion 24b is generated and the first visible light transmissive portion 24a is not generated. That is, the second visible light transmissive portion 24b is brought into the transmissive state, and the first visible light transmissive portion 24a is brought into the non-transmissive state.

As described above, in the electronic apparatus 50 according to the second specific example, the light regulating member 23 such as the liquid crystal shutter can selectively generate the plurality of visible light transmissive portions 24a and 24b having different sizes, so that the same sensor 5 can be used to generate a plurality of pieces of image data obtained by imaging the subject light transmitted through the visible light transmissive portions 24a and 24b having different sizes, and image data in which high-order light components of diffracted light are suppressed can be generated on the basis of such pieces of image data.

In the first and second specific examples described above, the example in which the plurality of transmissive windows having different sizes or visible light transmissive portions having different sizes is provided in the non-light emitting region 6c in the first pixel region 6 has been described, but the transmissive windows or the visible light transmissive portions are similar in shape to each other (for example, rectangular). On the other hand, a plurality of transmissive windows having different shapes or visible light transmissive portions having different shapes may be provided in the non-light emitting region 6c. When the shapes of the transmissive windows or the visible light transmissive portions are changed, the generation direction of diffracted light changes. It is therefore possible to obtain, by providing a plurality of transmissive windows having different shapes or visible light transmissive portions having different shapes in the non-light emitting region 6c, a plurality of pieces of image data different in generation direction of diffracted light from each other, and remove diffracted light by means of image processing on the basis of such pieces of image data.

As a more specific example, it is conceivable to provide at least one pixel including a transmissive window different in shape from the first transmissive window 6d1 in the non-light emitting region 6c in at least one of FIG. 25B or 25C. The transmissive window having a different shape may be a transmissive window having a shape (for example, a circle) other than a rectangle, or may be a transmissive window having a rectangular shape of which a ratio between a long side and a short side is changed. Since the generation directions of diffracted light contained in image data captured through the plurality of transmissive windows having different shapes are different from each other, it is possible to identify and remove the diffracted light contained in the plurality of pieces of image data captured through the plurality of transmissive windows having different shapes in a relatively simple manner. It is therefore possible to remove the first-order light component of the diffracted light that cannot be removed by the image processing unit 22 in FIG. 27 or the image processing unit 22a in FIG. 30.

### (Application Example of Image Display Device 1 and Electronic Apparatus 50 According to Present Disclosure)

### First application example

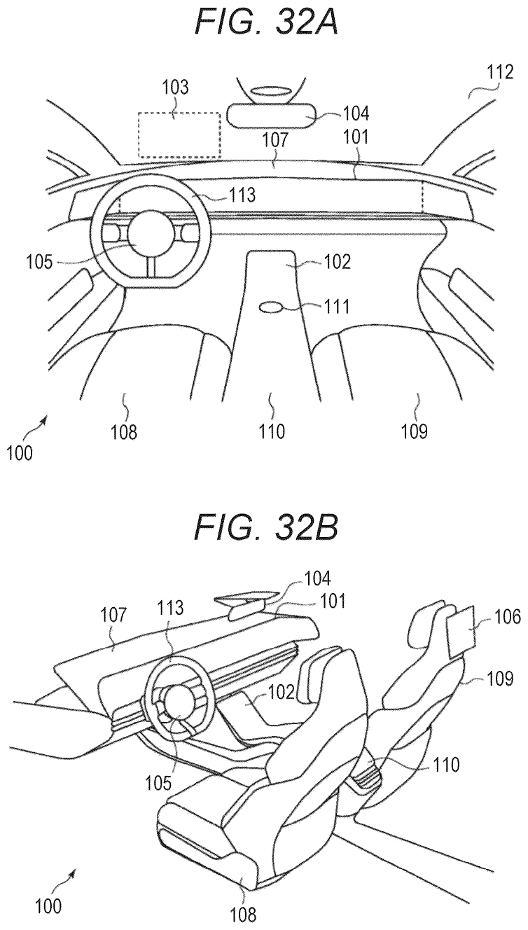

The image display device 1 and the electronic apparatus 50 according to the present disclosure can be used for various purposes. FIGS. 32A and 32B are diagrams illustrating an internal configuration of a vehicle 100 as a first application example of the electronic apparatus 50 including the image display device 1 according to the present disclosure. FIG. 32A is a diagram illustrating an internal state of the vehicle 100 as viewed from a rear side to a front side of the vehicle 100, and FIG. 32B is a diagram illustrating an internal state of the vehicle 100 as viewed from an oblique rear side to an oblique front side of the vehicle 100.

The vehicle 100 in FIGS. 32A and 32B includes a center display 101, a console display 102, a head-up display 103, a digital rear mirror 104, a steering wheel display 105, and a rear entertainment display 106.

The center display 101 is arranged on a dashboard 107 at a location facing a driver seat 108 and a passenger seat 109. FIG. 32 illustrates an example of the center display 101 having a horizontally long shape extending from the driver seat 108 side to the passenger seat 109 side, but any screen size and arrangement location of the center display 101 may be adopted. The center display 101 can display information detected by the various sensors 5. As a specific example, the center display 101 can display a captured image captured by an image sensor, an image of a distance to an obstacle in front of or on a side of the vehicle, the distance being measured by a ToF sensor, a passenger's body temperature detected by an infrared sensor, and the like. The center display 101 can be used to display, for example, at least one of safety-related information, operation-related information, a life log, health-related information, authentication/identification-related information, or entertainment-related information.

The safety-related information is information of doze detection, looking-aside detection, detection of a child passenger getting into mischief, wearing or not wearing of a seat belt, detection of leaving of an occupant behind, and the like, and is information detected by the sensor 5 arranged, for example, to overlap with the back surface side of the center display 101. The operation-related information is a gesture related to an operation by the occupant detected by using the sensor 5. The detected gesture may include an operation of various types of equipment in the vehicle 100. For example, operations of air conditioning equipment, a navigation device, an audiovisual (AV) device, a lighting device, and the like are detected. The life log includes life logs of all the occupants. For example, the life log includes an action record of each occupant in the vehicle. By acquiring and storing the life log, it is possible to check a state of the occupant at a time of an accident. In the health-related information, the health condition of the occupant is estimated on the basis of the body temperature of the occupant detected by using a temperature sensor. Alternatively, the face of the occupant may be imaged by using an image sensor, and the health condition of the occupant may be estimated from the imaged facial expression. Moreover, automated voice conversations may be made with the occupant, and the health condition of the occupant may be estimated on the basis of the content of the answer from the occupant. The authentication/identification-related information includes a keyless entry function of performing face authentication by using the sensor 5, a function of automatically adjusting a seat height and position by means of face identification, and the like. The entertainment-related information includes a function of detecting, with the sensor 5, operation information regarding the AV device being used by the occupant, and a function of recognizing the face of the occupant with the sensor 5 and providing content suitable for the occupant through the AV device.

The console display 102 can be used, for example, to display the life log information. The console display 102 is arranged near a shift lever 111 of a center console 110 between the driver seat 108 and the passenger seat 109. The console display 102 can also display information detected by the various sensors 5. Furthermore, the console display 102 may display an image of the surroundings of the vehicle captured by an image sensor, or may display an image of a distance to an obstacle present in the surroundings of the vehicle.

The head-up display 103 is virtually displayed behind a windshield 112 in front of the driver seat 108. The head-up display 103 can be used to display, for example, at least one of the safety-related information, the operation-related information, the life log, the health-related information, the authentication/identification-related information, or the entertainment-related information. Since the head-up display 103 is virtually arranged in front of the driver seat 108 in many cases, the head-up display 103 is suitable for displaying information directly related to an operation of the vehicle 100, such as a speed of the vehicle 100 and a remaining amount of fuel (battery).

The digital rear mirror 104 can not only display the rear side of the vehicle 100 but also a state of the occupant in the rear seat, and thus can be used to display, for example, the life log information by arranging the sensor 5 to overlap with the back surface side of the digital rear mirror 104.

The steering wheel display 105 is arranged near the center of a steering wheel 113 of the vehicle 100. The steering wheel display 105 can be used to display, for example, at least one of the safety-related information, the operation-related information, the life log, the health-related information, the authentication/identification-related information, or the entertainment-related information. In particular, since the steering wheel display 105 is close to the driver's hand, the steering wheel display 105 is suitable for displaying the life log information such as the body temperature of the driver, or for displaying information regarding an operation of the AV device, air conditioning equipment, or the like.

The rear entertainment display 106 is attached to the back side of the driver seat 108 and the passenger seat 109, and is for the occupant in the rear seat to view. The rear entertainment display 106 can be used to display, for example, at least one of the safety-related information, the operation-related information, the life log, the health-related information, the authentication/identification-related information, or the entertainment-related information. In particular, since the rear entertainment display 106 is in front of the occupant in the rear seat, information related to the occupant in the rear seat is displayed. For example, information regarding an operation of the AV device or the air conditioning equipment may be displayed, or a result of measuring the body temperature or the like of the occupant in the rear seat by the temperature sensor may be displayed.

As described above, by arranging the sensor 5 to overlap with the back surface side of the image display device 1, a distance to an object that is present in the surroundings can be measured. Optical distance measurement methods are roughly classified into a passive type and an active type. In the passive type method, a distance is measured by receiving light from the object without projecting light from the sensor 5 to the object. The passive type method includes a lens focus method, a stereo method, a monocular vision method, and the like. In the active type method, a distance is measured by projecting light onto the object and receiving reflected light from the object with the sensor 5. The active type method includes an optical radar method, an active stereo method, an illuminance difference stereo method, a moire topography method, an interference method, and the like. The image display device 1 according to the present disclosure can be applied to any of these types of distance measurement. By using the sensor 5 arranged to overlap with the back surface side of the image display device 1 according to the present disclosure, the distance measurement of the passive type or the active type described above can be performed.

### Second Application Example

The image display device 1 according to the present disclosure is applicable not only to various displays used in vehicles but also to displays mounted on various electronic apparatuses 50.

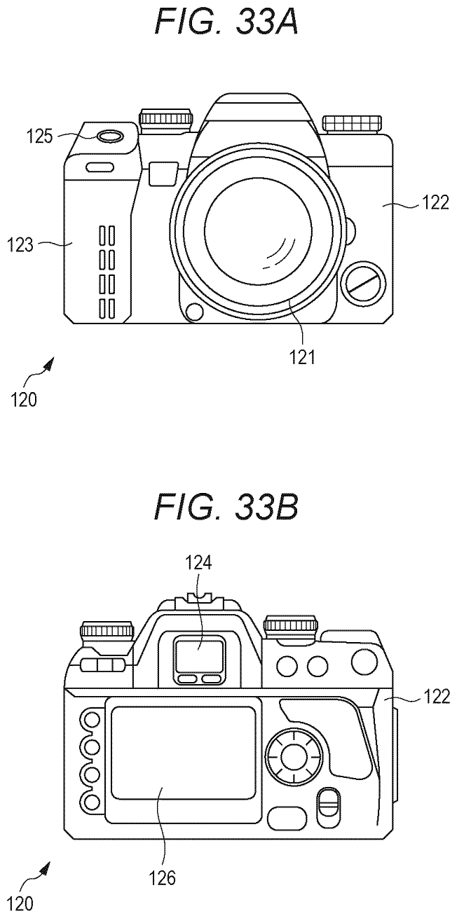

FIG. 33A is a front view of a digital camera 120 as a second application example of the electronic apparatus 50, and FIG. 33B is a rear view of the digital camera 120. The digital camera 120 in FIGS. 33A and 33B is an example of a single-lens reflex camera in which a lens 121 is replaceable, but the electronic apparatus 50 is also applicable to a camera in which the lens 121 is not replaceable.

In the camera in FIGS. 33A and 33B, when a person who captures an image looks into an electronic viewfinder 124 to determine a composition while holding a grip 123 of a camera body 122, and presses a shutter 125 while adjusting focus, captured image data is stored in a memory in the camera. As illustrated in FIG. 33B, on a back side of the camera, a monitor screen 126 that displays the captured image data and the like and a live image and the like, and the electronic viewfinder 124 are provided. Furthermore, there is a case where a sub screen that displays setting information such as a shutter speed and an exposure value is provided on the upper surface of the camera.

By arranging the sensor 5 so as to overlap with the back surface side of the monitor screen 126, the electronic viewfinder 124, the sub screen, and the like used for the camera, the camera can be used as the image display device 1 according to the present disclosure.

### Third Application Example

The image display device 1 according to the present disclosure is also applicable to a head mounted display (hereinafter, referred to as HMD). The HMD can be used for virtual reality (VR), augmented reality (AR), mixed reality (MR), substitutional reality (SR), or the like.

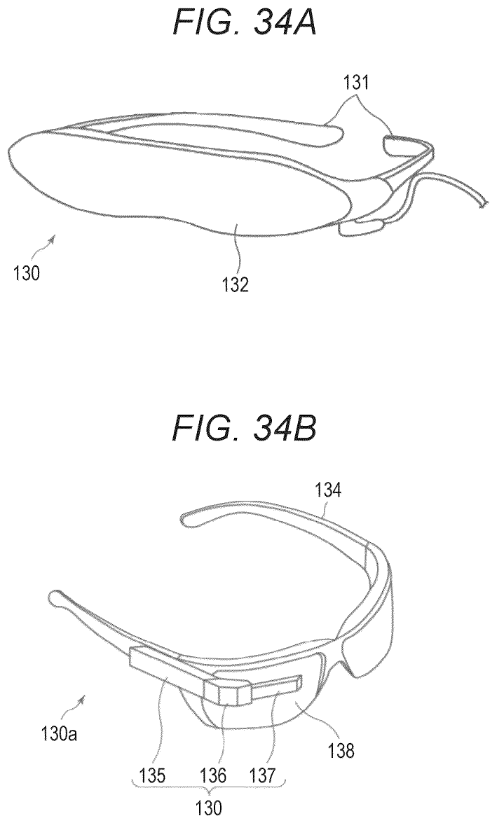

FIG. 34A is an external view of an HMD 130 as a third application example of the electronic apparatus 50. The HMD 130 in FIG. 34A includes a mounting member 131 for attachment to cover human eyes. The mounting member 131 is, for example, hooked and fixed to human ears. A display device 132 is provided inside the HMD 130, and a wearer of the HMD 130 can visually recognize a stereoscopic image and the like with the display device 132. The HMD 130 includes, for example, a wireless communication function and an acceleration sensor, and can switch a stereoscopic image and the like displayed on the display device 132 in accordance with a posture, a gesture, and the like of the wearer.

Furthermore, a camera may be provided in the HMD 130 to capture an image around the wearer, and an image obtained by combining the image captured by the camera and an image generated by a computer may be displayed on the display device 132. For example, by arranging the camera to overlap with the back surface side of the display device 132 visually recognized by the wearer of the HMD 130, capturing an image of the surroundings of the eyes of the wearer with the camera, and displaying the captured image on another display provided on the outer surface of the HMD 130, a person around the wearer can obtain expression of the face and a movement of the eyes of the wearer in real time.

Note that various types of the HMD 130 are conceivable. For example, as illustrated in FIG. 34B, the image display device 1 according to the present disclosure is also applicable to smart glasses 130a that displays various types of information on glasses 134. The smart glasses 130a in FIG. 34B includes a main body portion 135, an arm portion 136, and a lens barrel portion 137. The main body portion 135 is connected to the arm portion 136. The main body portion 135 is detachable from the glasses 134. The main body portion 135 incorporates a display unit and a control board for controlling the operation of the smart glasses 130a. The main body portion 135 and the lens barrel portion 137 are connected to each other via the arm portion 136. The lens barrel portion 137 emits image light emitted from the main body portion 135 through the arm portion 136, toward a lens 138 of the glasses 134. This image light enters the human eyes through the lens 138. The wearer of the smart glasses 130a in FIG. 34B can visually recognize not only a surrounding situation but also various pieces of information emitted from the lens barrel portion 137 similarly to normal glasses.

### Fourth Application Example

The image display device 1 according to the present disclosure is also applicable to a television device (hereinafter, a TV). In recent TVs, a frame tends to be as small as possible from the viewpoint of downsizing and design properties. Therefore, in a case where a camera to capture an image of a viewer is provided on a TV, it is desirable to arrange the camera so as to overlap with the back surface side of a display panel 2 of the TV.

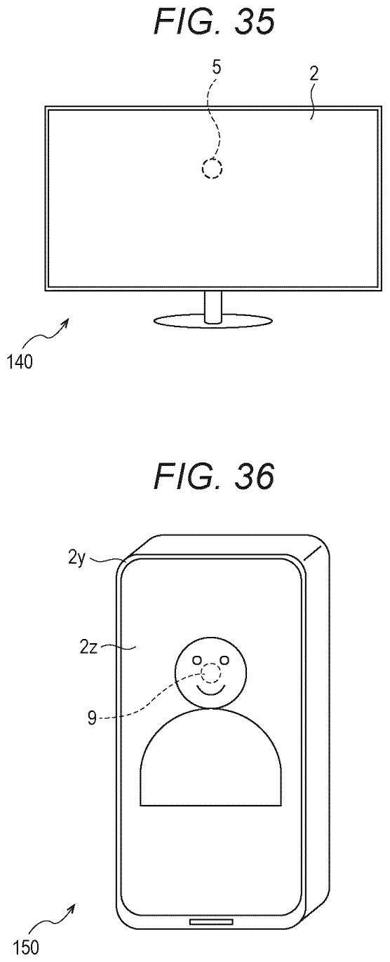

FIG. 35 is an external view of a TV 140 as a fourth application example of the electronic apparatus 50. In the TV 140 in FIG. 35, the frame is minimized, and almost the entire region on the front side is a display area. The TV 140 incorporates a sensor 5 such as a camera to capture the image of the viewer. The sensor 5 in FIG. 35 is arranged on the back side of a part (for example, a broken line part) in the display panel 2. The sensor 5 may be an image sensor module, or various sensors can be applied such as a sensor for face authentication, a sensor for distance measurement, and a temperature sensor, and a plurality of types of sensors may be arranged on the back surface side of the display panel 2 of the TV 140.

As described above, according to the image display device 1 of the present disclosure, the image sensor module 9 can be arranged to overlap with the back surface side of the display panel 2. Therefore, there is no need to arrange a camera or the like on the frame, the TV 140 can be downsized, and there is no possibility that the design is impaired by the frame.

### Fifth Application Example

The image display device 1 according to the present disclosure is also applicable to a smartphone and a mobile phone. FIG. 36 is an external view of a smartphone 150 as a fifth application example of the electronic apparatus 50. In an example in FIG. 36, a display surface 2z extends to nearly the outer shape of the electronic apparatus 50, and the width of a bezel 2y around the display surface 2z is set to several millimeters or less. In general, a front camera is often mounted on the bezel 2y, but in FIG. 36, as indicated by a broken line, the image sensor module 9 serving as the front camera is arranged on, for example, the back surface side of a substantially central portion of the display surface 2z. As described above, by providing the front camera on the back surface side of the display surface 2z in this manner, the front camera is no longer necessary to be arranged on the bezel 2y, and thus the width of the bezel 2y can be narrowed.

Note that the present technology may have the following configurations.

(1) An image display device including:
a plurality of pixels arranged two-dimensionally; and
a pixel region including some pixels of the plurality of pixels, the pixel region including two or more transmissive windows that transmit visible light and have different sizes, in which
the some pixels include:
a self light-emitting element;
a light emitting region in which light is emitted by the self light-emitting element; and
a non-light emitting region including the transmissive window.

(2) The image display device according to (1), in which each of the two or more transmissive windows is arranged for a corresponding one of the pixels or arranged across two or more of the pixels.

(3) The image display device according to (2), in which the some pixels include two or more pixels, and
each of the two or more pixels includes one of the two or more transmissive windows having different sizes.

(4) The image display device according to (3), in which the light emitting region in each of the two or more pixels includes a plurality of the self light-emitting elements that emits light in different colors.

(5) The image display device according to (3) or (4), in which the two or more pixels include:
a first pixel including the self light-emitting element, the light emitting region, and the non-light emitting region including the transmissive window having a first size; and
a second pixel including the self light-emitting element, the light emitting region, and the non-light emitting region including the transmissive window having a second size different from the first size.

(6) The image display device according to (5), in which the transmissive window having the first size and the transmissive window having the second size are similar in shape to each other.

(7) The image display device according to (5) or (6), in which the pixel region includes:
a first pixel group in which a plurality of the first pixels is two-dimensionally arranged; and
a second pixel group in which a plurality of the second pixels is two-dimensionally arranged,
a ratio of an interval between the transmissive windows to a width of each of the transmissive windows in the first pixel group is a first prime number, and
a ratio of an interval between the transmissive windows to a width of each of the transmissive windows in the second pixel group is a second prime number different from the first prime number.

(8) The image display device according to (7), in which the plurality of first pixels in the first pixel group is arranged in multiple rows and columns in a first direction and a second direction,
the plurality of second pixels in the second pixel group is arranged in multiple rows and columns in the first direction and the second direction,
a ratio of an interval between the transmissive windows in the first pixel group to a width of each of the transmissive windows in the first direction is equal to a ratio of an interval between the transmissive windows in the first pixel group to a width of each of the transmissive windows in the second direction, and
a ratio of an interval between the transmissive windows in the second pixel group to a width of each of the transmissive windows in the first direction is equal to a ratio of an interval between the transmissive windows in the second pixel group to a width of each of the transmissive windows in the second direction.

(9) The image display device according to (7) or (8), in which one of the first prime number or the second prime number is 2, and the other is 3.

(10) The image display device according to any one of (2) to (9), in which the some pixels include three or more pixels,
the three or more pixels include any one of three or more of the transmissive windows having different sizes, and ratios of respective intervals of the three or more transmissive windows to respective widths of the three or more transmissive windows are different prime numbers.

(11) The image display device according to (1), further including:
a pixel array unit including the plurality of pixels; and
a light regulating member arranged on a surface side opposite to a display surface of the pixel array unit and arranged so as to overlap the pixel array unit as viewed from above, in which
the light regulating member selectively generates one of two or more visible light transmissive portions having different sizes at a position overlapping a corresponding one of the transmissive windows as viewed from above.

(12) The image display device according to (11), in which a size of each of the visible light transmissive portions is smaller than or equal to the size of each of the transmissive windows.

(13) The image display device according to (11) or (12), in which the some pixels include two or more pixels,
each of the two or more pixels includes the two or more transmissive windows having different sizes, and the light regulating member selectively generates the two or more visible light transmissive portions different in position and size in accordance with positions and the sizes of the two or more transmissive windows.

(14) The image display device according to any one of (11) to (13), in which the light regulating member selectively generates one of the two or more visible light transmissive portions under electrical control or mechanical control.

(15) The image display device according to (14), in which the light regulating member includes a liquid crystal shutter configured to partially vary visible light transmittance, and
the liquid crystal shutter varies a transmittance of a region corresponding to the two or more transmissive windows to generate any one of the two or more visible light transmissive portions.

(16) An image display device including:
a pixel array unit including a plurality of pixels arranged two-dimensionally; and
a light regulating member arranged on a surface side opposite to a display surface of the pixel array unit and arranged so as to overlap the pixel array unit as viewed from above, in which
a pixel region including some pixels of the plurality of pixels includes a transmissive window that transmits visible light,
the some pixels include:
a self light-emitting element;
a light emitting region in which light is emitted by the self light-emitting element; and
a non-light emitting region including the transmissive window, and
the light regulating member selectively generates one of two or more visible light transmissive portions having different sizes at a position overlapping the transmissive window as viewed from above.

(17) The image display device according to (16), in which the light regulating member includes a liquid crystal shutter configured to partially vary visible light transmittance, and
the liquid crystal shutter varies transmittances of two or more partial regions in a region corresponding to the transmissive window to generate any one of the two or more visible light transmissive portions.

(18) The image display device according to any one of (1) to (17), in which the non-light emitting region is arranged at a position overlapping a light receiving device configured to receive light incident through the plurality of pixels as a display surface side of the plurality of pixels is viewed from above.

(19) An electronic apparatus including:
an image display device including a plurality of pixels arranged two-dimensionally; and
a light receiving device configured to receive light incident through the image display device, in which
the image display device includes a pixel region including some pixels of the plurality of pixels,
the pixel region includes an opening through which visible light is transmitted,
the some pixels include:
a self light-emitting element;
a light emitting region in which light is emitted by the self light-emitting element; and
a non-light emitting region including the opening, at least a part of the pixel region is arranged so as to overlap the light receiving device as a display surface side of the image display device is viewed from above, and
the light receiving device receives two or more rays of subject light selectively transmitted through two or more of the openings having different sizes or two or more regions having different sizes in the opening.

(20) The electronic apparatus according to (19), further including a signal processing unit configured to cancel out a high-order light component of diffracted light on the basis of a light reception signal based on the two or more rays of subject light received by the light receiving device.

(21) The electronic apparatus according to (19) or (20), in which the light receiving device includes at least one of: an imaging sensor configured to photoelectrically convert light incident through the non-light emitting region; a distance measuring sensor configured to receive the light incident through the non-light emitting region to measure a distance; or a temperature sensor configured to measure a temperature on the basis of the light incident through the non-light emitting region.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Image display device
2 Display panel
2a Display layer
2b Anode
2c Hole injection layer
2d Hole transport layer
2e Light-emitting layer
2f Electron transport layer
2g Electron injection layer
2h Cathode
2y Bezel
2z Display surface
3 Flexible printed circuit
4 Chip
5 Sensor
5a First sensor
5b Second sensor
6 First pixel region
6a First self light-emitting element
6b First light emitting region
6c Non-light emitting region
6d Transmissive window
6d Visible light transmissive window
6d1 First transmissive window
6d2 Second transmissive window
7 Pixel
8 Second pixel region
8a Second self light-emitting element
8b Second light emitting region
9 Image sensor module
9a Support substrate
9b Image sensor
9c Cut filter
9d Lens unit
9e Coil
9f Magnet
9g Spring
10 Subject
12 Pixel circuit
12a Anode electrode
14 Diffraction grating
15 Screen
21 Multiplier
22, 22a Image processing unit
23 Light regulating member
24a First visible light transmissive portion
24b Second visible light transmissive portion
25 Liquid crystal shutter
26 Liquid crystal shutter control unit
31 First transparent substrate
32 First insulating layer
33 First wiring layer
34 Second insulating layer
34a Trench
35 Second wiring layer
35a Contact member
36 Third insulating layer
36a Trench
36b Contact member
37 Fourth insulating layer
37a Recess
38 Anode electrode layer
39 Cathode electrode layer
40 Fifth insulating layer
41 Second transparent substrate
42 Semiconductor layer
50 Electronic apparatus
100 Vehicle
101 Center display
102 Console display
203 Head-up display
104 Digital rear mirror
105 Steering wheel display
106 Rear entertainment display
107 Dashboard
108 Driver seat
109 Passenger seat
110 Center console
111 Shift lever
112 Windshield
113 Steering wheel
120 Digital camera
121 Lens
122 Camera body
123 Grip
124 Electronic viewfinder
125 Shutter
126 Monitor screen
130a Smart glasses
131 Mounting member
132 Display device
134 Glasses
135 Main body portion
136 Arm portion
137 Lens barrel portion
138 Lens
150 Smartphone

1. An image display device comprising:
a plurality of pixels arranged two-dimensionally; and
a pixel region including some pixels of the plurality of pixels, the pixel region including two or more transmissive windows that transmit visible light and have different sizes, wherein
the some pixels include:
a self light-emitting element;
a light emitting region in which light is emitted by the self light-emitting element; and
a non-light emitting region including the transmissive window.

2. The image display device according to claim 1, wherein each of the two or more transmissive windows is arranged for a corresponding one of the pixels or arranged across two or more of the pixels.

3. The image display device according to claim 2, wherein the some pixels include two or more pixels, and
each of the two or more pixels includes one of the two or more transmissive windows having different sizes.

4. The image display device according to claim 3, wherein the light emitting region in each of the two or more pixels includes a plurality of the self light-emitting elements that emits light in different colors.

5. The image display device according to claim 3, wherein the two or more pixels include:
a first pixel including the self light-emitting element, the light emitting region, and the non-light emitting region including the transmissive window having a first size; and
a second pixel including the self light-emitting element, the light emitting region, and the non-light emitting region including the transmissive window having a second size different from the first size.

6. The image display device according to claim 5, wherein the transmissive window having the first size and the transmissive window having the second size are similar in shape to each other.

7. The image display device according to claim 5, wherein the pixel region includes:
a first pixel group in which a plurality of the first pixels is two-dimensionally arranged; and
a second pixel group in which a plurality of the second pixels is two-dimensionally arranged,
a ratio of an interval between the transmissive windows to a width of each of the transmissive windows in the first pixel group is a first prime number, and
a ratio of an interval between the transmissive windows to a width of each of the transmissive windows in the second pixel group is a second prime number different from the first prime number.

8. The image display device according to claim 7, wherein the plurality of first pixels in the first pixel group is arranged in multiple rows and columns in a first direction and a second direction,
the plurality of second pixels in the second pixel group is arranged in multiple rows and columns in the first direction and the second direction,
a ratio of an interval between the transmissive windows in the first pixel group to a width of each of the transmissive windows in the first direction is equal to a ratio of an interval between the transmissive windows in the first pixel group to a width of each of the transmissive windows in the second direction, and
a ratio of an interval between the transmissive windows in the second pixel group to a width of each of the transmissive windows in the first direction is equal to a ratio of an interval between the transmissive windows in the second pixel group to a width of each of the transmissive windows in the second direction.

9. The image display device according to claim 7, wherein one of the first prime number or the second prime number is 2, and another is 3.

10. The image display device according to claim 2, wherein the some pixels include three or more pixels,
the three or more pixels include any one of three or more of the transmissive windows having different sizes, and ratios of respective intervals of the three or more transmissive windows to respective widths of the three or more transmissive windows are different prime numbers.

11. The image display device according to claim 1, further comprising:
a pixel array unit including the plurality of pixels; and
a light regulating member arranged on a surface side opposite to a display surface of the pixel array unit and arranged so as to overlap the pixel array unit as viewed from above, wherein
the light regulating member selectively generates one of two or more visible light transmissive portions having different sizes at a position overlapping a corresponding one of the transmissive windows as viewed from above.

12. The image display device according to claim 11, wherein a size of each of the visible light transmissive portions is smaller than or equal to the size of each of the transmissive windows.

13. The image display device according to claim 11, wherein the some pixels include two or more pixels,
each of the two or more pixels includes the two or more transmissive windows having different sizes, and the light regulating member selectively generates the two or more visible light transmissive portions different in position and size in accordance with positions and the sizes of the two or more transmissive windows.

14. The image display device according to claim 11, wherein the light regulating member selectively generates one of the two or more visible light transmissive portions under electrical control or mechanical control.

15. The image display device according to claim 14, wherein the light regulating member includes a liquid crystal shutter configured to partially vary visible light transmittance, and
the liquid crystal shutter varies a transmittance of a region corresponding to the two or more transmissive windows to generate any one of the two or more visible light transmissive portions.

16. An image display device comprising:
a pixel array unit including a plurality of pixels arranged two-dimensionally; and
a light regulating member arranged on a surface side opposite to a display surface of the pixel array unit and arranged so as to overlap the pixel array unit as viewed from above, wherein
a pixel region including some pixels of the plurality of pixels includes a transmissive window that transmits visible light,
the some pixels include:
a self light-emitting element;
a light emitting region in which light is emitted by the self light-emitting element; and
a non-light emitting region including the transmissive window, and
the light regulating member selectively generates one of two or more visible light transmissive portions having different sizes at a position overlapping the transmissive window as viewed from above.

17. The image display device according to claim 16, wherein the light regulating member includes a liquid crystal shutter configured to partially vary visible light transmittance, and
the liquid crystal shutter varies transmittances of two or more partial regions in a region corresponding to the transmissive window to generate any one of the two or more visible light transmissive portions.

18. The image display device according to claim 1, wherein the non-light emitting region is arranged at a position overlapping a light receiving device configured to receive light incident through the plurality of pixels as a display surface side of the plurality of pixels is viewed from above.

19. An electronic apparatus comprising:
an image display device including a plurality of pixels arranged two-dimensionally; and
a light receiving device configured to receive light incident through the image display device, wherein
the image display device includes a pixel region including some pixels of the plurality of pixels,
the pixel region includes an opening through which visible light is transmitted,
the some pixels include:
a self light-emitting element;
a light emitting region in which light is emitted by the self light-emitting element; and
a non-light emitting region including the opening,
at least a part of the pixel region is arranged so as to overlap the light receiving device as a display surface side of the image display device is viewed from above, and
the light receiving device receives two or more rays of subject light selectively transmitted through two or more of the openings having different sizes or two or more regions having different sizes in the opening.

20. The electronic apparatus according to claim 19, further comprising a signal processing unit configured to cancel out a high-order light component of diffracted light on a basis of a light reception signal based on the two or more rays of subject light received by the light receiving device.

21. The electronic apparatus according to claim 19, wherein the light receiving device includes at least one of: an imaging sensor configured to photoelectrically convert light incident through the non-light emitting region; a distance measuring sensor configured to receive the light incident through the non-light emitting region to measure a distance; or a temperature sensor configured to measure a temperature on a basis of the light incident through the non-light emitting region.
